(19) United States
(12) Patent Application Publication
(10) Pub. No.: US 2022/0270691 A1
(43) Pub. Date: Aug. 25, 2022

(54) SEMICONDUCTOR STORAGE DEVICE

(71) Applicant: KIOXIA CORPORATION, Tokyo (JP)

(72) Inventors: Yousuke TAMURA, Fujisawa Kanagawa (JP); Yasuyuki MATSUDA, Yokohama Kanagawa (JP)

(21) Appl. No.: 17/459,572

(22) Filed: Aug. 27, 2021

(30) Foreign Application Priority Data
Feb. 24, 2021 (JP) 2021-027242

(51) Int. Cl. G11C 16/34; G11C 16/04; G11C 16/14; G11C 16/26

(52) U.S. Cl. CPC G11C 16/3436; G11C 16/0483; G11C 16/14; G11C 16/26

(57) ABSTRACT

A semiconductor storage device includes a plurality of planes, the planes including a first plane and a second plane, an interface circuit configured to receive and transmit control signals for the planes, and a control circuit configured to control the planes based on the control signals. While a first operation that includes multiple loops of a high voltage operation and a verify operation is being performed by the first plane, the control circuit controls the second plane to perform a second operation during at least one period in which the verify operation is performed by the first plane.

### CROSS-REFERENCE TO RELATED APPLICATION(S)

This application is based upon and claims the benefit of priority from Japanese Patent Application No. 2021-027242, filed Feb. 24, 2021, the entire contents of which are incorporated herein by reference.

### FIELD

Embodiments described herein relate generally to a semiconductor storage device.

### BACKGROUND

In a semiconductor storage device such as a NAND flash memory, for example, data are stored in a memory cell array. As such a semiconductor storage device, a semiconductor storage device having a plurality of planes, each of which has a memory cell array, is also known.

### BRIEF DESCRIPTION OF THE DRAWINGS

FIG. 1 is a block diagram illustrating an example of a configuration of a memory system according to a first embodiment.

FIG. 2 is a block diagram illustrating a configuration of a semiconductor storage device according to the first embodiment.

FIG. 3 is a block diagram illustrating a configuration of a sequencer.

FIG. 4 is a block diagram illustrating a configuration of a register.

FIG. 5 is a block diagram illustrating a configuration of a voltage generation circuit.

FIG. 6 is an equivalent circuit diagram illustrating a configuration of a memory cell array.

FIG. 7 is a cross-sectional view illustrating the configuration of the memory cell array.

FIG. 8 is a diagram illustrating a circuit configuration of a sense amplifier unit.

FIG. 9 is a diagram illustrating an example of a threshold voltage distribution of a memory cell transistor.

FIG. 10 is a diagram illustrating voltage changes in various wirings during a write operation.

FIG. 11 is a diagram illustrating a relationship between the number of loops and a verify operation during the write operation.

FIG. 12 is a diagram illustrating voltage changes in various wirings during the write operation.

FIG. 13 is a diagram illustrating voltage changes in a word line during the write operation.

FIGS. 14A to 14F are diagrams illustrating voltage changes in word lines in different planes during the write operation.

FIGS. 15A to 15D are diagrams illustrating voltage changes in word lines in different planes during a write operation of a comparative example.

FIGS. 16A to 16F are diagrams illustrating voltage changes in word lines in different planes during a write operation of a semiconductor storage device according to a second embodiment.

FIGS. 17A to 17D are diagrams illustrating voltage changes in word lines in different planes during a write operation of a semiconductor storage device according to a third embodiment.

FIGS. 18A to 18D are diagrams illustrating voltage changes in word lines in different planes during a write operation of a semiconductor storage device according to a fourth embodiment.

FIG. 19 is a diagram illustrating voltage changes in various wirings during a read operation.

FIG. 20 is a diagram illustrating voltage changes in word lines in various wirings during the read operation of a lower page.

FIG. 21 is a diagram illustrating voltage changes in word lines in various wirings during the read operation of a middle page.

FIG. 22 is a diagram illustrating voltage changes in word lines in various wirings during the read operation of an upper page.

### DETAILED DESCRIPTION

Embodiments provide a semiconductor storage device capable of speeding up operations performed thereon.

In general, according to one embodiment, a semiconductor storage device includes a plurality of planes, each of which has a memory cell array, the planes including a first plane and a second plane, an interface circuit configured to receive and transmit control signals for the planes, and a control circuit configured to control the planes based on the control signals. While a first operation that includes multiple loops of a high voltage operation and a verify operation is being performed by the first plane, the control circuit controls the second plane to perform a second operation during at least one period in which the verify operation is performed by the first plane.

Hereinafter, embodiments of the present disclosure will be described with reference to the accompanying drawings. In order to facilitate the understanding of descriptions, the same components in the respective drawings will be denoted by the same reference numerals, and descriptions thereof will be omitted.

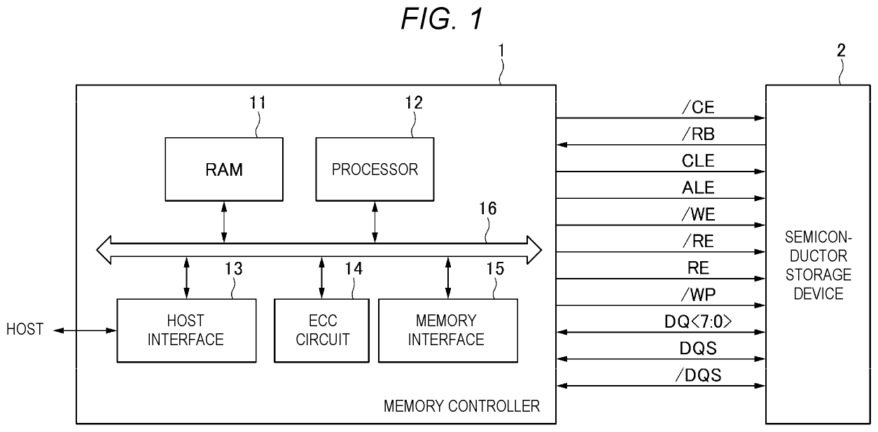

A first embodiment will be described. A semiconductor storage device 2 according to the first embodiment is a nonvolatile storage device configured as a NAND flash memory. FIG. 1 illustrates an example of a configuration of a memory system that includes the semiconductor storage device 2, in a block diagram. This memory system includes a memory controller 1 and the semiconductor storage device 2. The specific configuration of the semiconductor storage device 2 will be described later. The memory system of FIG. 1 may be connected to a host (not illustrated) . The host is, for example, an electronic device such as a personal computer or a mobile terminal.

The memory controller 1 controls write of data to the semiconductor storage device 2 according to a write request from the host. Further, the memory controller 1 controls read of data from the semiconductor storage device 2 according to a read request from the host.

A chip enable signal /CE, a ready busy signal /RB, a command latch enable signal CLE, an address latch enable signal ALE, a write enable signal /WE, read enable signals RE and /RE, a write protect signal /WP, a data signal DQ<7:0>, and data strobe signals DQS and /DQS are transmitted and received between the memory controller 1 and the semiconductor storage device 2.

The chip enable signal /CE is a signal for enabling the semiconductor storage device 2. The ready busy signal /RB is a signal for indicating whether the semiconductor storage device 2 is in a ready state or in a busy state. The “ready state” is a state in which an external command can be received. The “busy state” is a state in which an external command cannot be received. The command latch enable signal CLE is a signal indicating that the signal DQ<7:0> contains a command. The address latch enable signal ALE is a signal indicating that the signal DQ<7:0> contains an address. The write enable signal /WE is a signal for inputting a received signal into the semiconductor storage device 2 and is asserted each time a command, an address, and data are received from the memory controller 1. The memory controller 1 instructs the semiconductor storage device 2 to input the signal DQ<7:0> while the signal /WE is at an “L (Low)” level.

The read enable signals RE and /RE are signals for enabling the memory controller 1 to read data from the semiconductor storage device 2. These signals are used, for example, to control the operation timing of the semiconductor storage device 2 when the signal DQ<7:0> is output. The write protect signal /WP is a signal for instructing the semiconductor storage device 2 to prohibit data write and erase. The signal DQ<7:0> contains data transmitted and received between the semiconductor storage device 2 and the memory controller 1, and includes commands, addresses, and data. The data strobe signals DQS and /DQS are signals for controlling the input/output the timing of the signal DQ<7:0>.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to each other by an internal bus 16.

The host interface 13 outputs a request received from the host, user data (e.g., write data), and the like to the internal bus 16. Further, the host interface 13 transmits user data read from the semiconductor storage device 2, a response from the processor 12, and the like to the host.

The memory interface 15 controls a process of writing user data and the like to the semiconductor storage device 2 and a process of reading user data from the semiconductor storage device 2 based on an instruction of the processor 12.

The processor 12 controls the operations of the memory controller 1. The processor 12 is, for example, a CPU, an MPU, or the like. When a request is received from the host via the host interface 13, the processor 12 performs a control according to the request. For example, the processor 12 instructs the memory interface 15 to write user data and parity to the semiconductor storage device 2 according to the request from the host. Further, the processor 12 instructs the memory interface 15 to read the user data and the parity from the semiconductor storage device 2 according to the request from the host.

The processor 12 determines a storage area (also referred to as memory area) in the semiconductor storage device 2 for user data stored in the RAM 11. The user data are stored in the RAM 11 via the internal bus 16. The processor 12 determines the memory area for a page unit of data (also referred to as page data) which is a unit of writing. The user data stored on one page of the semiconductor storage device 2 are hereinafter also referred to as “unit data.” The unit data are generally encoded and stored in the semiconductor storage device 2 as a code word. In embodiments described herein, encoding is optional. The memory controller 1 may store the unit data in the semiconductor storage device 2 without encoding, but FIG. 1 illustrates a configuration in which encoding is performed, as a configuration example. When the memory controller 1 does not perform the encoding, the page data matches the unit data. Further, one code word may be generated based on one unit data, or one code word may be generated based on divided data obtained by dividing the unit data. Further, one code word may be generated using a plurality of unit data.

The processor 12 determines the memory area of the semiconductor storage device 2 as a write destination for each unit data. A physical address is allocated to the memory area of the semiconductor storage device 2. The processor 12 manages the memory area of the write destination of the unit data by using the physical address. The processor 12 instructs the memory interface 15 to designate the determined memory area (e.g., the physical address) and write the user data to the semiconductor storage device 2. The processor 12 manages the correspondence between a logical address of the user data (a logical address managed by the host) and the physical address. When a read request including a logical address is received from the host, the processor 12 specifies the physical address that corresponds to the logical address, and instructs the memory interface 15 to designate the physical address and read the user data.

The ECC circuit 14 encodes the user data stored in the RAM 11 to generate a code word. Further, the ECC circuit 14 decodes a code word read from the semiconductor storage device 2.

The RAM 11 temporarily stores the user data received from the host before being stored in the semiconductor storage device 2, or temporarily stores the data read from the semiconductor storage device 2 before being transmitted to the host. The RAM 11 is, for example, a general-purpose memory such as an SRAM or DRAM.

FIG. 1 illustrates an example of a configuration in which the memory controller 1 includes the ECC circuit 14 and the memory interface 15. However, the ECC circuit 14 may be integrated with the memory interface 15. Further, the ECC circuit 14 may be integrated with the semiconductor storage device 2. The specific configuration or arrangement of each element illustrated in FIG. 1 is to be understood as non-limiting.

When a write request is received from the host, the memory system illustrated in FIG. 1 operates as follows. The processor 12 temporarily stores data which is the target of the write operation, in the RAM 11. The processor 12 reads the data stored in the RAM 11, and inputs the read data to the ECC circuit 14. The ECC circuit 14 encodes the input data, and inputs a code word to the memory interface 15. The memory interface 15 writes the input code word to the semiconductor storage device 2.

When the read request is received from the host, the memory system illustrated in FIG. 1 operates as follows. The memory interface 15 inputs a code word read from the semiconductor storage device 2, to the ECC circuit 14. The ECC circuit 14 decodes the input code word and stores the decoded data in the RAM 11. The processor 12 transmits the data stored in the RAM 11 to the host via the host interface 13.

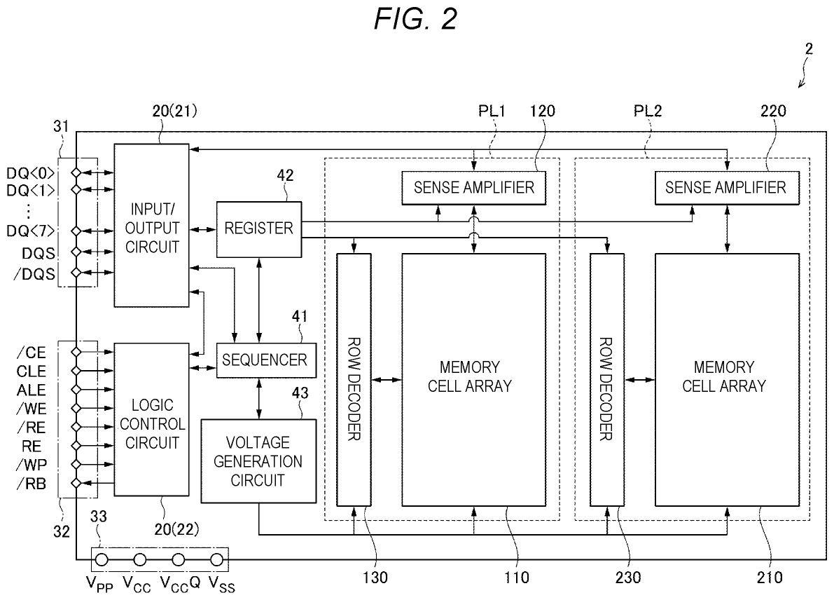

The configuration of the semiconductor storage device 2 will be described mainly with reference to FIG. 2. As illustrated in FIG. 2, the semiconductor storage device 2 includes two planes PL1 and PL2, an input/output circuit 21, a logic control circuit 22, a sequencer 41, a register 42, a voltage generation circuit 43, and a pad group 31 for input/output, a pad group 32 for logic control, and a terminal group 33 for power input.

The plane PL1 includes a memory cell array 110, a sense amplifier 120, and a row decoder 130. Further, the plane PL2 includes a memory cell array 210, a sense amplifier 220, and a row decoder 230. The plane PL1 has the same configuration as the plane PL2. That is, the memory cell array 110 has the same configuration as the memory cell array 210, the sense amplifier 120 has the same configuration as the sense amplifier 220, and the row decoder 130 has the same configuration as the row decoder 230. The number of planes provided in the semiconductor storage device 2 may be two as in the present embodiment, but may be three or more.

The memory cell array 110 and the memory cell array 210 are structures for storing data. Each of the memory cell array 110 and the memory cell array 210 includes a plurality of memory cell transistors associated with a word line and a bit line, which will be described in more detail later.

The input/output circuit 21 transmits/receives the signal DQ<7:0> and the data strobe signals DQS and/DQS to/from the memory controller 1. The input/output circuit 21 transfers a command and an address in the signal DQ<7:0> to the register 42. Further, the input/output circuit 21 transmits/receives write data and read data to/from the sense amplifier 120 and the sense amplifier 220.

The logic control circuit 22 receives the chip enable signal /CE, the command latch enable signal CLE, the address latch enable signal ALE, the write enable signal /WE, the read enable signals RE and /RE, and the write protect signal /WP from the memory controller 1. Further, the logic control circuit 22 transfers the ready busy signal /RB to the memory controller 1 to notify the state of the semiconductor storage device 2 to the outside.

Both the input/output circuit 21 and the logic control circuit 22 are circuits to and from which signals are input/output from and to the memory controller 1. The input/output circuit 21 and the logic control circuit 22 are hereinafter collectively referred to as an “interface circuit 20.” The interface circuit 20 may be said to be circuit to and from which a signal including a control signal related to the operations of the planes PL1 and PL2 is input/output. The above-described “control signal” is, for example, a command and an address in the signal DQ<7:0> input to the input/output circuit 21, the command latch enable signal CLE input to the logic control circuit 22, or the like.

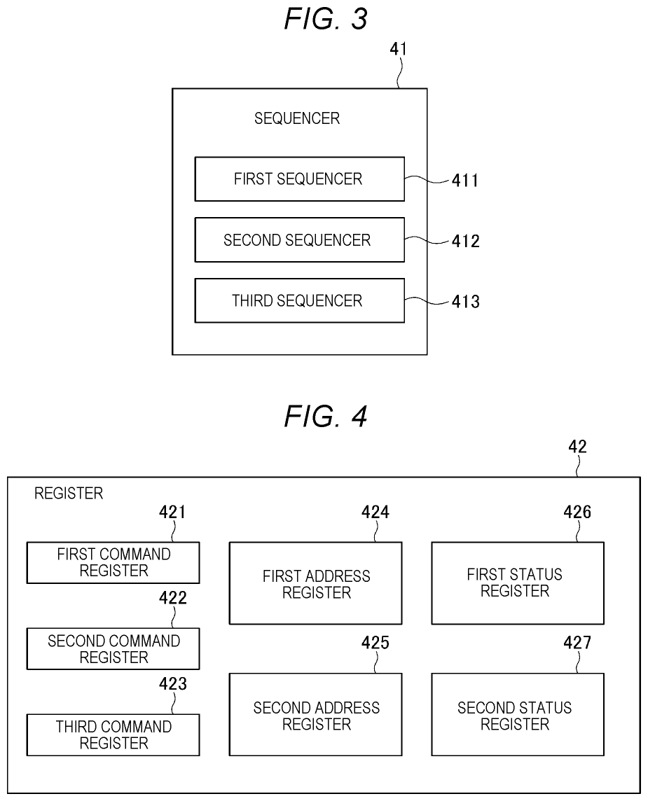

The sequencer 41 controls the operation of each circuit of semiconductor storage device 2 such as the planes PL1 and PL2 and the voltage generation circuit 43 based on the control signal input from the memory controller 1 to the interface circuit 20. The sequencer 41 corresponds to a “control circuit” in the embodiments. Both the sequencer 41 and the logic control circuit 22 may also be regarded as the “control circuit” in the embodiments. As illustrated in FIG. 3, the sequencer 41 includes a first sequencer 411, a second sequencer 412, and a third sequencer 413.

The first sequencer 411 is a circuit that performs a process required for the write operation or erase operation of the planes PL1 and PL2. The first sequencer 411 starts its operation, for example, when a command is stored in a first command register 421 (see FIG. 4) which will be described later. The first sequencer 411 also collectively performs a process of controlling the operations of the second sequencer 412 and the third sequencer 413.

The second sequencer 412 is a circuit that performs a process required for the read operation of the plane PL1. The second sequencer 412 starts its operation, for example, when a command is stored in a second command register 422 (see FIG. 4) which will be described later.

The third sequencer 413 is a circuit that performs a process required for the read operation of the plane PL2. The third sequencer 413 starts its operation, for example, when a command is stored in a third command register 423 (see FIG. 4) which will be described later.

The above-described distribution of functions in the first sequencer 411, the second sequencer 412, and the third sequencer 413 is merely an example. For example, the functions of the first sequencer 411 and the like may be changed each time according to the order of commands stored in the registers. The specific contents of the processes performed by the sequencer 41 will be described later.

The register 42 of FIG. 2 is a circuit that temporarily stores a command and an address. As illustrated in FIG. 4, the register 42 includes a first command register 421, a second command register 422, a third command register 423, a first address register 424, a second address register 425, and a first status register 426, and a second status register 427.

The first command register 421 is a circuit that stores a command instructing the write operation or erase operation of the planes PL1 and PL2. The command is input from the memory controller 1 to the input/output circuit 21 and is then transferred from the input/output circuit 21 to the first command register 421 and is stored in the first command register 421.

The second command register 422 is a circuit that stores a command instructing the read operation of the plane PL1. The command is input from the memory controller 1 to the input/output circuit 21 and is then transferred from the input/output circuit 21 to the second command register 422 and is stored in the second command register 422.

The third command register 423 is a circuit that stores a command instructing read operation of the plane PL2. The command is input from the memory controller 1 to the input/output circuit 21 and is then transferred from the input/output circuit 21 to the third command register 423 and is stored in the third command register 423.

The first address register 424 is a circuit that stores an address corresponding to the command to the plane PL1. The address is input from the memory controller 1 to the input/output circuit 21 and is then transferred from the input/output circuit 21 to the first address register 424 and is stored in the first address register 424.

The second address register 425 is a circuit that stores an address corresponding to the command to the plane PL2. The address is input from the memory controller 1 to the input/output circuit 21 and is then transferred from the input/output circuit 21 to the second address register 425 and is stored in the second address register 425.

The first status register 426 is a circuit that stores first status information indicating the status of the plane PL1. The first status information stored in the first status register 426 is updated by the sequencer 41 each time according to the operation state of the plane PL1. The first status information is output from the input/output circuit 21 to the memory controller 1 as a status signal in response to a request from the memory controller 1.

The second status register 427 is a circuit that stores second status information indicating the status of the plane PL2. The second status information is updated by the sequencer 41 each time according to the operation state of the plane PL2. The second status information stored in the second status register 427 is output from the input/output circuit 21 to the memory controller 1 as a status signal in response to a request from the memory controller 1.

Since the register 42 includes the first status register 426 and the second status register 427 as described above, the sequencer 41 may perform a process for outputting the status signal indicating the status of each of the planes PL1 and PL2 from the interface circuit 20 in response to the request from the memory controller 1.

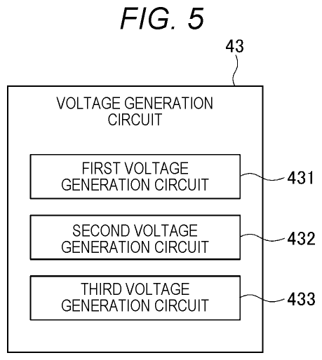

The voltage generation circuit 43 of FIG. 2 is a circuit that generates a voltage required for each of the write operation, read operation, and erase operation of data in the memory cell arrays 110 and 210 based on an instruction from the sequencer 41. As illustrated in FIG. 5, the voltage generation circuit 43 includes a first voltage generation circuit 431, a second voltage generation circuit 432, and a third voltage generation circuit 433.

The first voltage generation circuit 431 is a circuit that generates a voltage required for the write operation and erase operation of data in the planes PL1 and PL2. Such a voltage includes, for example, a voltage such as VPGM or VPASS_PGM applied to a word line WL which will be described later, a voltage applied to a bit line BL which will be described later, or the like.

The second voltage generation circuit 432 is a circuit that generates a voltage required for the read operation of data in the plane PL1. Such a voltage includes, for example, a voltage such as VrA or VPASS_READ applied to the word line WL, a voltage applied to the bit line BL, or the like.

The third voltage generation circuit 433 is a circuit that generates a voltage required for the read operation of data in the plane PL2. Such a voltage includes, for example, a voltage such as VrA or VPASS_READ applied to the word line WL, a voltage applied to the bit line BL, or the like.

The above-described distribution of functions in the first voltage generation circuit 431, the second voltage generation circuit 432, and the third voltage generation circuit 433 is merely an example. The voltage generation circuit 43 may be configured such that a voltage may be individually applied to each of the word line WL, the bit line BL, and the like, so as to enable the plane PL1 and the plane PL2 to operate in parallel with each other.

The pad group 31 for input/output is provided with a plurality of terminals (also referred to as pads) for transmitting and receiving each signal between the memory controller 1 and the input/output circuit 21. Each terminal is individually provided corresponding to each of the signals in DQ<7:0> and the data strobe signals DQS and /DQS.

The pad group 32 for logic control is provided with a plurality of terminals (pads) for transmitting and receiving each signal between the memory controller 1 and the logic control circuit 22. Each terminal is individually provided corresponding to each of the chip enable signal /CE, the command latch enable signal CLE, the address latch enable signal ALE, the write enable signal /WE, the read enable signals RE and /RE, the write protect signal /WP, and the ready busy signal /RB.

The terminal group 33 for power input is provided with a plurality of terminals for receiving the application of each voltage required for the operation of the semiconductor storage device 2. The voltages applied to the terminals include power supply voltages Vcc, VccQ, and Vpp and a ground voltage Vss.

The power supply voltage Vcc is a circuit power supply voltage given from the outside, as an operation power supply, which is, for example, a voltage of about 3.3 V. The power supply voltage VccQ is, for example, a voltage of 1.2 V. The power supply voltage VccQ is a voltage used to transmit and receive a signal between the memory controller 1 and the semiconductor storage device 2. The power supply voltage Vpp is a power supply voltage higher than the power supply voltage Vcc, which is, for example, a voltage of 12 V.

When data is written to or erased from the memory cell arrays 110 and 210, a high voltage of about 20 V is required. At this time, boosting the power supply voltage Vpp of about 12 V may generate a desired voltage at a higher speed and with a lower power consumption than boosting the power supply voltage Vcc of about 3.3 V by a booster circuit of the voltage generation circuit 43. Meanwhile, for example, when the semiconductor storage device 2 is used in an environment where a high voltage cannot be supplied, a voltage may not be supplied to the power supply voltage Vpp. Even when the power supply voltage Vpp is not supplied, the semiconductor storage device 2 may execute various operations as long as the power supply voltage Vcc is supplied. That is, the power supply voltage Vcc is a power supply that is supplied to the semiconductor storage device 2, as standard, and the power supply voltage Vpp is a power supply that is additionally and optionally supplied according to, for example, the usage environment.

The configuration of the planes PL1 and PL2 will be described. As described above, the plane PL1 has the same configuration as the plane PL2. Therefore, in the following, only the configuration of the plane PL1 will be described, and the illustration and description of the configuration of the plane PL2 will be omitted.

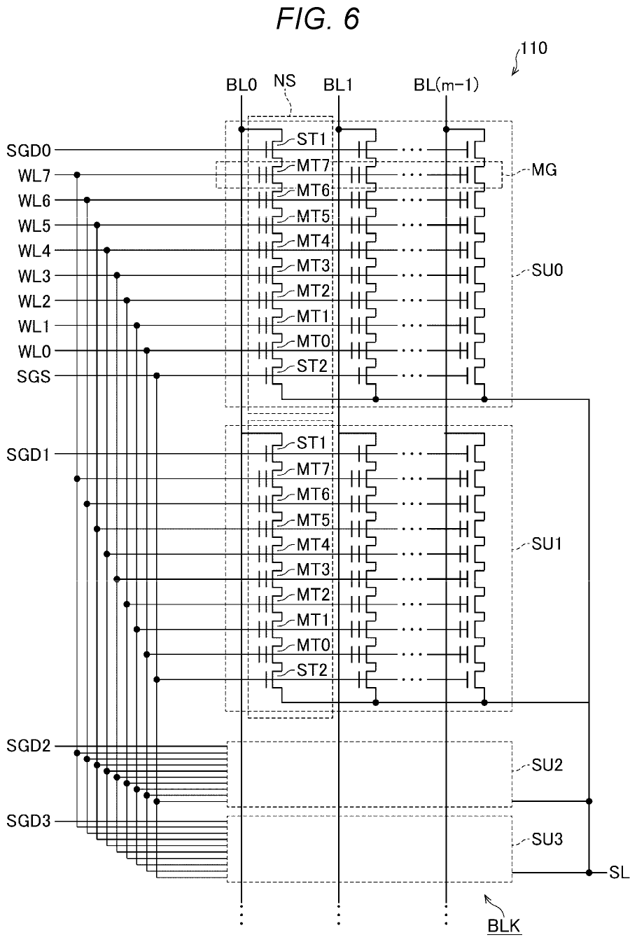

FIG. 6 illustrates the configuration of the memory cell array 110 provided on the plane PL1, as an equivalent circuit diagram. While the memory cell array 110 is configured by a plurality of blocks BLK, FIG. 6 illustrates only one block BLK of the plurality of blocks BLK. The configuration of the other block BLK included in the memory cell array 110 is also the same as that illustrated in FIG. 6.

As illustrated in FIG. 6, the block BLK includes, for example, four string units SU (SU0 to SU3). Further, each string unit SU includes a plurality of NAND strings NS. Each of the NAND strings NS includes, for example, eight memory cell transistors MT (MT0 to MT7) and select transistors ST1 and ST2.

The number of memory cell transistors MT is not limited to eight, but may be, for example, 32, 48, 64, or 96. For example, in order to improve the cutoff characteristic, each of the select transistors ST1 and ST2 may be configured by a plurality of transistors, rather than a single transistor. Further, a dummy cell transistor may be provided between the memory cell transistor MT and the select transistors ST1 and ST2.

The memory cell transistors MT are disposed so as to be connected in series between the select transistor ST1 and the select transistor ST2. The memory cell transistor MT7 on one end side is connected to the source of the select transistor ST1, and the memory cell transistor MT0 on the other end side is connected to the drain of the select transistor ST2.

The gates of the select transistors ST1 of the string units SU0 to SU3 are connected in common to select gate lines SGD0 to SGD3, respectively. The gates of the select transistors ST2 are connected in common to the same select gate line SGS across a plurality of string units SU in the same block BLK. The control gates of the memory cell transistors MT0 to MT7 in the same block BLK are connected in common to word lines WL0 to WL7, respectively. That is, the word lines WL0 to WL7 and the select gate line SGS are common among the plurality of string units SU0 to SU3 in the same block BLK, whereas the select gate lines SGD are provided individually for each of the string unit SU0 to SU3 even in the same block BLK.

The memory cell array 110 is provided with an “m” number of bit lines BL (BL0, BL1, . . . BL(m-1)). The “m” is an integer that represents the number of NAND strings NS included in one string unit SU. Of the respective NAND strings NS, the drain of the select transistor ST1 is connected to the corresponding bit line BL. The source of the select transistor ST2 is connected to a source line SL. The source line SL is connected in common to the sources of the plurality of select transistors ST2 included in the block BLK.

Data stored in a plurality of memory cell transistors MT in the same block BLK are collectively erased. Meanwhile, read and write of the data are collectively performed for a plurality of memory cell transistors MT connected to one word line WL and belonging to one string unit SU. Each memory cell may store 3-bit data that includes a high-order bit, a middle-order bit, and a low-order bit.

That is, the semiconductor storage device 2 according to the present embodiment employs a TLC method for storing 3-bit data in one memory cell transistor MT as a method for writing data to the memory cell transistor MT. Instead of the TLC method, an MLC method for storing 2-bit data in one memory cell transistor MT or an SLC method for storing 1-bit data in one memory cell transistor MT may be employed.

In the following description, a set of 1-bit data stored by a plurality of memory cell transistors MT connected to one word line WL and belonging to one string unit SU is referred to as a “page.” In FIG. 6, one of the sets including the plurality of memory cell transistors MT as described above is denoted by a symbol “MG.”

When 3-bit data is stored in one memory cell transistor MT as in the present embodiment, a set of a plurality of memory cell transistors MT connected to the common word line WL in one string unit SU may store data for 3 pages.

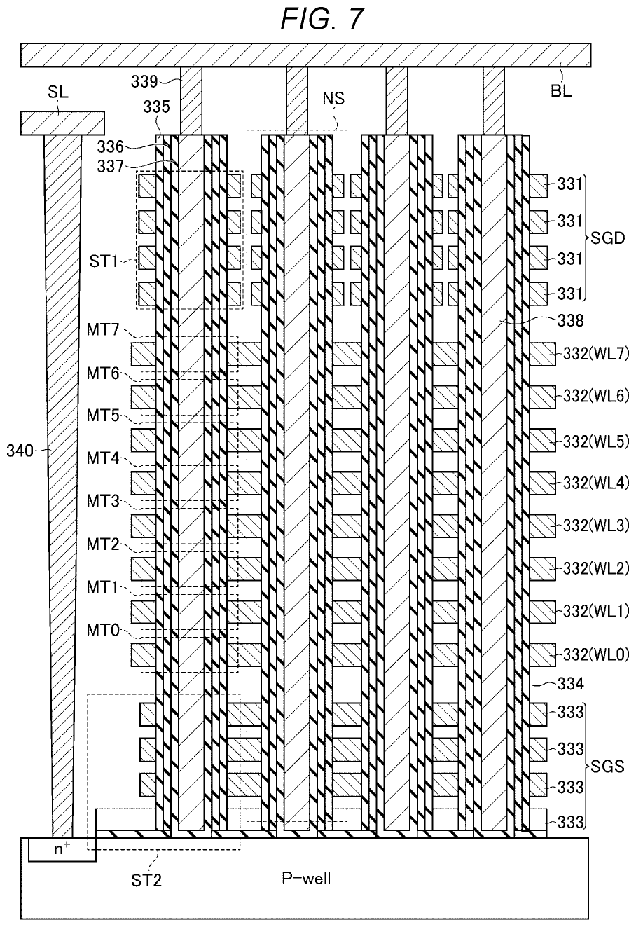

FIG. 7 illustrates the configuration of the memory cell array 110 as a schematic cross-sectional view. As illustrated in FIG. 7, in the memory cell array 110, a plurality of NAND strings NS are formed on a p-type well region (P-well) of a silicon substrate. A plurality of wiring layers 333 each functioning as a select gate line SGS, a plurality of wiring layers 332 each functioning as a word line WL, and a plurality of wiring layers 331 each functioning as a select gate line SGD are stacked above the p-type well region. Insulating layers (not illustrated) are disposed between the stacked wiring layers 333, 332, and 331.

A plurality of memory holes 334 are formed in the memory cell array 110. A memory hole 334 is a hole formed so as to penetrate the wiring layers 333, 332, and 331 and the insulating layers (not illustrated) among the wiring layers 333, 332, and 331 in the vertical direction and reach the p-type well region. A block insulating film 335, a charge storage layer 336, and a gate insulating film 337 are sequentially formed on the side surface of the memory hole 334, and a conductive column 338 is further buried inside the gate insulating film 337. The conductive column 338 is made of, for example, polysilicon, and functions as a region where a channel is formed during the operation of the memory cell transistors MT and the select transistors ST1 and ST2 included in the NAND string NS. In this way, a columnar body configured by the block insulating film 335, the charge storage layer 336, the gate insulating film 337, and the conductive column 338 is formed inside the memory hole 334.

Of the columnar body formed inside the memory hole 334, each portion intersecting each of the stacked wiring layers 333, 332, and 331 functions as a transistor. Of these plurality of transistors, a transistor located at a portion intersecting the wiring layer 331 functions as the select transistor ST1. Of the plurality of transistors, a transistor located at a portion intersecting the wiring layer 332 functions as the memory cell transistor MT (MT0 to MT7). Of the plurality of transistors, a transistor located at a portion intersecting the wiring layer 333 functions as the select transistor ST2. With such a configuration, each columnar body formed inside each memory hole 334 functions as the NAND string NS described with reference to FIG. 6.

A wiring layer that functions as a bit line BL is formed above the conductive column 338. A contact plug 339 that connects the conductive column 338 and the bit line BL is formed at the upper end of the conductive column 338.

Further, an n⁺-type impurity diffusion layer and a p⁺-type impurity diffusion layer (not illustrated) are formed in the surface of the p-type well region. A contact plug 340 is formed on the n⁺-type impurity diffusion layer, and a wiring layer that functions as the source line SL is formed on the contact plug 340.

A plurality of configurations similar to the configuration illustrated in FIG. 7 are arranged along the depth direction of the paper surface of FIG. 7. One string unit SU is formed by a set of a plurality of NAND strings NS arranged in a plane that extends in the depth direction of the paper surface of FIG. 7.

Descriptions will be continued referring back to FIG. 2. As described above, the plane PL1 is provided with the sense amplifier 120 and the row decoder 130, in addition to the above-described memory cell array 110.

The sense amplifier 120 is a circuit for adjusting the voltage applied to the bit line BL or reading the voltage of the bit line BL and converting it into data. During data read, the sense amplifier 120 acquires the read data read from the memory cell transistor MT to the bit line BL and transfers the acquired read data to the input/output circuit 21. During data write, the sense amplifier 120 transfers the write data written via the bit line BL to the memory cell transistor MT.

The row decoder 130 is a circuit configured as a switch group (not illustrated) for applying a voltage to each word line WL. The row decoder 130 receives a block address and a row address from the register 42, selects a corresponding block BLK based on the block address, and selects a corresponding word line WL based on the row address. The row decoder 130 switches opening/closing of the switch group so that a voltage from the voltage generation circuit 43 is applied to the selected word line WL.

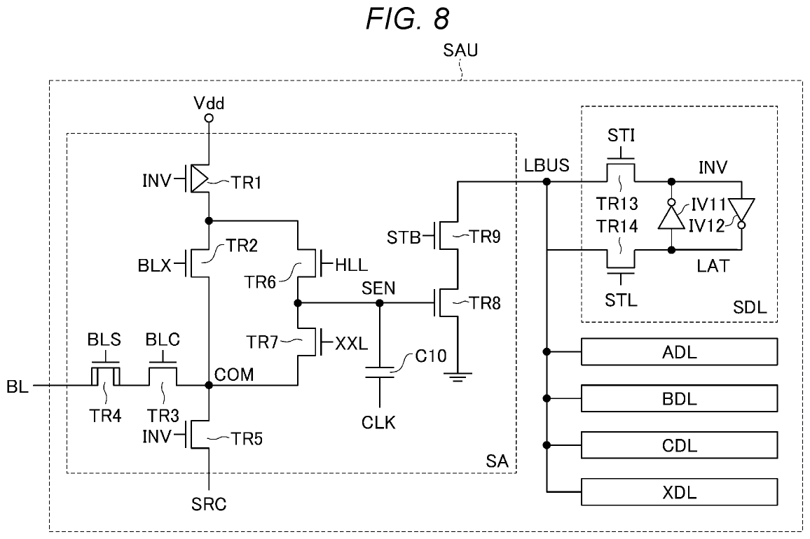

FIG. 8 illustrates an example of a configuration of the sense amplifier 120. The sense amplifier 120 includes a plurality of sense amplifier units SAU associated with each of the plurality of bit lines BL. FIG. 8 represents a detailed circuit configuration of one sense amplifier unit SAU extracted from the sense amplifier units SAU.

As illustrated in FIG. 8, the sense amplifier unit SAU includes a sense amplifier part SA and latch circuits SDL, ADL, BDL, CDL, and XDL. The sense amplifier unit SA, and the latch circuits SDL, ADL, BDL, CDL, and XDL are connected by a bus LBUS so as to exchange data with each other.

For example, in the read operation, the sense amplifier unit SA senses the read data on the corresponding bit line BL and determines whether the read data is “0” or “1.” The sense amplifier part SA includes, for example, a transistor TR1 which is a p-channel MOS transistor, transistors TR2 to TR9 which are n-channel MOS transistors, and a capacitor C10.

One end of the transistor TR1 is connected to a power supply line, and the other end of the transistor TR1 is connected to the transistor TR2. The gate of the transistor TR1 is connected to a node INV in the latch circuit SDL. One end of the transistor TR2 is connected to the transistor TR1, and the other end of the transistor TR2 is connected to a node COM. A signal BLX is input to the gate of the transistor TR2. One end of the transistor TR3 is connected to the node COM, and the other end of the transistor TR3 is connected to the transistor TR4. A signal BLC is input to the gate of the transistor TR3. The transistor TR4 is a high breakdown voltage MOS transistor. One end of the transistor TR4 is connected to the transistor TR3. The other end of the transistor TR4 is connected to the corresponding bit line BL. A signal BLS is input to the gate of the transistor TR4.

One end of the transistor TR5 is connected to the node COM, and the other end of the transistor TR5 is connected to a node SRC. The gate of the transistor TR5 is connected to the node INV. One end of the transistor TR6 is connected between the transistor TR1 and the transistor TR2, and the other end of the transistor TR6 is connected to a node SEN. A signal HLL is input to the gate of the transistor TR6. One end of the transistor TR7 is connected to the node SEN, and the other end of the transistor TR7 is connected to the node COM. A signal XXL is input to the gate of the transistor TR7.

One end of the transistor TR8 is grounded, and the other end of the transistor TR8 is connected to the transistor TR9. The gate of the transistor TR8 is connected to the node SEN. One end of the transistor TR9 is connected to the transistor TR8, and the other end of the transistor TR9 is connected to the bus LBUS. A signal STB is input to the gate of the transistor TR9. One end of the capacitor C10 is connected to the node SEN. A clock CLK is input to the other end of the capacitor C10.

The signals BLX, BLC, BLS, HLL, XXL, and STB are generated by, for example, the sequencer 41. Further, for example, a voltage Vdd, which is the internal power supply voltage of the semiconductor storage device 2, is applied to the power supply line connected to one end of the transistor TR1, and for example, a voltage Vss, which is the ground voltage of the semiconductor storage device 2, is applied to the node SRC.

The latch circuits SDL, ADL, BDL, CDL, and XDL temporarily hold the read data. The latch circuit XDL is connected to the input/output circuit 21 and is used during transfer of data between the sense amplifier unit SAU and the input/output circuit 21.

The latch circuit SDL includes, for example, inverters IV11 and IV12 and transistors TR13 and TR14 which are n-channel MOS transistors. The input node of the inverter IV11 is connected to a node LAT. The output node of the inverter IV11 is connected to the node INV. The input node of the inverter IV12 is connected to the node INV. The output node of the inverter IV12 is connected to the node LAT. One end of the transistor TR13 is connected to the node INV, and the other end of the transistor TR13 is connected to the bus LBUS. A signal STI is input to the gate of the transistor TR13. One end of the transistor TR13 is connected to the node LAT, and the other end of the transistor TR14 is connected to the bus LBUS. A signal STL is input to the gate of the transistor TR14. For example, the data held in the node LAT corresponds to the data held in the latch circuit SDL. Further, the data held in the node INV corresponds to the inverse of the data held in the node LAT. Since the circuit configuration of the latch circuits ADL, BDL, CDL, and XDL is the same as the circuit configuration of the latch circuit SDL, descriptions thereof will be omitted.

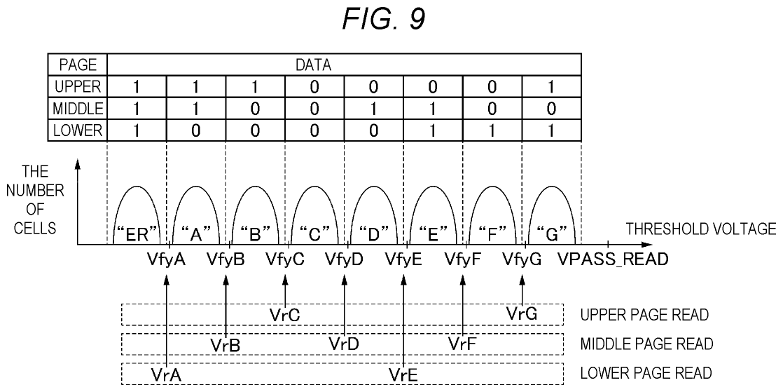

FIG. 9 is a diagram schematically illustrating a threshold voltage distribution and the like of the memory cell transistor MT. The figure in the middle section of FIG. 9 represents the relationship between the threshold voltage of the memory cell transistor MT (horizontal axis) and the number of memory cell transistors MT (vertical axis).

When the TLC method is employed as in the present embodiment, the plurality of memory cell transistors MT form eight threshold voltage distributions as illustrated in the middle section of FIG. 9. These eight threshold voltage distributions (which respectively correspond to write states) are referred to as an “ER” state, an “A” state, a “B” state, a “C” state, a “D” state, an “E” state, an “F” state, and a “G” state in an order from the lowest threshold voltage.

The table in the upper stage of FIG. 9 represents an example of data assigned to each of the above states of the threshold voltage. As represented in the table, for example, as represented below, different 3-bit data are assigned to the “ER” state, the “A” state, the “B” state, the “C” state, the “D” state, the “E” state, the “F” state, and the “G” state.

“ER” state: “111” (“lower bit/middle bit/upper bit”)

“A” state: “011”

“B” state: “001”

“C” state: “000”

“D” state: “010”

“E” state: “110”

“F” state: “100”

“G” state: “101”

A verify voltage used in write operation is set between a pair of adjacent threshold voltage distributions. Specifically, verify voltages VfyA, VfyB, VfyC, VfyD, VfyE, VfyF, and VfyG are set to correspond to the “A” state, the “B” state, the “C” state, the “D” state, the “E” state, the “F” state, and the “G” state, respectively.

The verify voltage VfyA is set between the maximum threshold voltage of the “ER” state and the minimum threshold voltage of the “A” state. When the verify voltage VfyA is applied to the memory cell transistor MT, the memory cell transistor MT whose threshold voltage is included in the “ER” state is turned ON and the memory cell transistor MT whose threshold voltage is included in the threshold voltage distribution equal to or higher than the “A” state is turned OFF.

The other verify voltages VfyB, VfyC, VfyD, VfyE, VfyF, and VfyG are also set in the same manner as the above verify voltage VfyA. The verify voltage VfyB is set between the “A” state and the “B” state, the verify voltage VfyC is set between the “B” state and the “C” state, the verify voltage VfyD is set between the “C” state and the “D” state, the verify voltage VfyE is set between the “D” state and the “E” state, the verify voltage VfyF is set between the “E” state and the “F” state, and the verify voltage VfyG is set between the “F” state and the “G” state.

For example, the verify voltages VfyA, VfyB, VfyC, VfyD, VfyE, VfyF, and VfyG may be set to 0.8V, 1.6V, 2.4V, 3.1V, 3.8V, 4.6V, and 5.6V, respectively. However, without being limited thereto, the verify voltages VfyA, VfyB, VfyC, VfyD, VfyE, VfyF, and VfyG may be appropriately and stepwise set in a range of, for example, 0 V to 7.0 V.

In addition, a read voltage used in read operation is set between the adjacent threshold voltage distributions. The “read voltage” is a voltage applied to a word line WL connected to a memory cell transistor MT to be read, that is, a selected word line WL, during the read operation. In the read operation, data is determined based on a result of determination about whether or not a threshold voltage of the memory cell transistor MT to be read is higher than the applied read voltage.

As schematically illustrated in the lower section of FIG. 9, specifically, a read voltage VrA used to determine whether the threshold voltage of the memory cell transistor MT is included in the “ER” state or in the “A” state or higher is set between the maximum threshold voltage of the “ER” state and the minimum threshold voltage of the “A” state.

Other read voltages VrB, VrC, VrD, VrE, VrF, and VrG are also set in the same manner as the above read voltage VrA. The read voltage VrB is set between the “A” state and the “B” state, the read voltage VrC is set between the “B” state and the “C” state, the read voltage VrD is set between the “C” state and the “D” state, the read voltage VrE is set between the “D” state and the “E” state, the read voltage VrF is set between the “E” state and the “F” state, and the read voltage VrG is set between the “F” state and the “G” state.

Then, a read pass voltage VPASS_READ is set to a voltage higher than the maximum threshold voltage of the highest threshold voltage distribution (for example, the “G” state). The memory cell transistor MT to which gate the read pass voltage VPASS_READ is applied is turned ON, regardless of data stored therein.

Further, for example, the verify voltages VfyA, VfyB, VfyC, VfyD, VfyE, VfyF, and VfyG are set to be voltages higher than the read voltages VrA, VrB, VrC, VrD, VrE, VrF, and VrG, respectively. That is, the verify voltages VfyA, VfyB, VfyC, VfyD, VfyE, VfyF, and VfyG are set to the vicinity of the minimum voltages of the threshold voltage distributions of the “A” state, the “B” state, the “C” state, the “D” state, the “E” state, the “F” state, the “G” state, respectively.

When the data assignment as described above is applied, one-page data of lower bits (lower page data) in the read operation may be determined by a read result using the read voltages VrA and VrE. One-page data of middle bits (middle page data) may be determined by a read result using the read voltages VrB, VrD, and VrF. One-page data of upper bits (upper page data) may be determined by a read result using the read voltages VrC and VrG. In this way, the lower page data, the middle page data, and the upper page data are determined by performing the read operation twice, three times, and twice, respectively. Therefore, the above data assignment is called a “2-3-2 code.”

The data assignment as described above is merely an example, but the actual data allocation is not limited thereto. For example, 2-bit or 4-bit or more data may be stored in one memory cell transistor MT. Further, the number of threshold voltage distributions to which data are allocated may be 7 or less, or 9 or more.

The write operation performed in the semiconductor storage device 2 will be described. In the write operation, a program operation and a verify operation are performed. The “program operation” is an operation of raising the threshold voltage of the memory cell transistor MT by injecting electrons into the charge storage layer 336 of the memory cell transistor MT. The program operation also includes maintaining the threshold voltage of the memory cell transistor MT by prohibiting the injection of electrons into the charge storage layer 336 of the memory cell transistor MT.

The “verify operation” is an operation of determining whether or not the threshold voltage of the memory cell transistor MT has reached a target state by reading data after the above program operation in the write operation. The memory cell transistor MT whose threshold voltage has reached the target state is, thereafter, write-prohibited.

In the write operation, a combination of the program operation and the verify operation is repeated. As a result, the threshold voltage of the memory cell transistor MT rises to the target state.

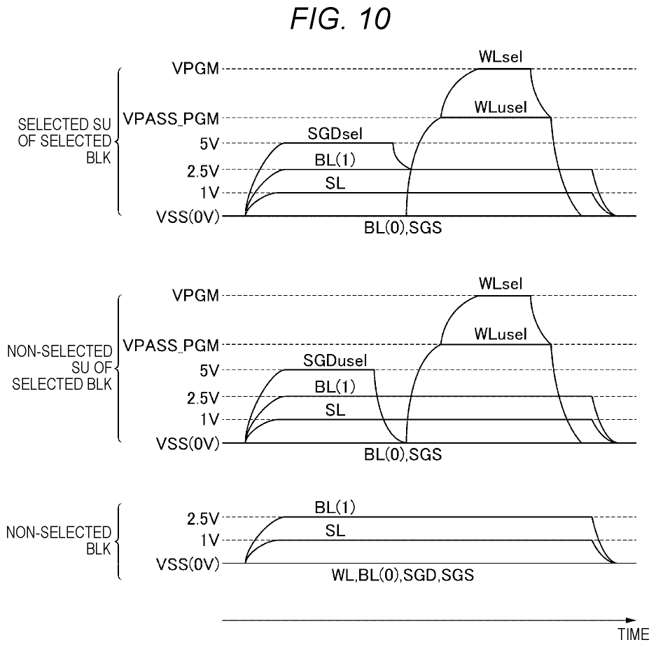

FIG. 10 illustrates voltage changes in various wirings during the program operation. Hereinafter, an example in which the program operation is performed on the plane PL1 will be described. In the program operation, the sense amplifier 120 changes the voltage of each bit line BL according to program data. The ground voltage Vss (e.g., 0 V) is applied as an “L” level to a bit line BL connected to a memory cell transistor MT (whose threshold voltage should be raised) to be programmed. On the other hand, 2.5 V is applied as an “H” level to a bit line BL connected to a memory cell transistor MT (whose threshold voltage needs to be maintained) not to be programmed. The former bit line BL is denoted as “BL(0)” in FIG. 10. The latter bit line BL is denoted as “BL(1)” in FIG. 10.

The row decoder 130 selects a block BLK as the target of the write operation and further selects a string unit SU. More specifically, for example, 5 V is applied from the voltage generation circuit 43 to a select gate line SGD (a selected select gate line SGDsel) in the selected string unit SU via the row decoder 130. As a result, the select transistor ST1 is turned ON. Meanwhile, for example, the voltage Vss is applied from the voltage generation circuit 43 to a select gate line SGS via the row decoder 130. As a result, the select transistor ST2 is turned OFF.

Further, for example, a voltage of 5 V is applied from the voltage generation circuit 43 to a select gate line SGD of a non-selected string unit SU in the selected block BLK (non-selected select gate line SGDusel) via the row decoder 130. As a result, the select transistor ST1 is turned ON. In the string unit SU included in each block BLK, the select gate line SGS is connected in common. Therefore, even in the non-selected string unit SU, the select transistor ST2 is turned OFF.

Further, for example, the voltage Vss is applied from the voltage generation circuit 43 to the select gate line SGD and the select gate line SGS in the non-selected block BLK via the row decoder 130. As a result, the select transistor ST1 and the select transistor ST2 are turned OFF.

The source line SL has a voltage, for example, 1 V, which is higher than the voltage of the select gate line SGS.

After that, the voltage of the selected select gate line SGDsel in the selected block BLK is set to, for example, 2.5 V. This voltage is sufficiently high to turn ON the select transistor ST1 corresponding to the bit line BL(0) to which 0 V is applied in the above example, but cuts off the select transistor ST1 corresponding to the bit line BL(1) to which 2.5 V is applied. As a result, in the selected string unit SU, the select transistor ST1 corresponding to the bit line BL(0) is turned ON, and the select transistor ST1 corresponding to the bit line BL(1) to which 2.5 V is applied is cut off. Meanwhile, the voltage of the non-selected select gate line SGDusel is, for example, the voltage Vss. As a result, in the non-selected string unit SU, the select transistor ST1 is cut off regardless of the voltages of the bit line BL(0) and the bit line BL(1).

Then, the row decoder 130 selects a word line WL as the target of the write operation in the selected block BLK. For example, a voltage VPGM is applied from the voltage generation circuit 43 to the word line WL that is the target of the write operation (selected word line WLsel) , via the row decoder 130. Meanwhile, for example, a voltage VPASS_PGM is applied from the voltage generation circuit 43 to the other word lines WL (non-selected word lines WLusel) via the row decoder 130. The voltage VPGM is a high voltage for injecting electrons into the charge storage layer 336 by the tunnel effect. The voltage VPASS_PGM is a voltage that does not change the threshold voltage while turning ON the memory cell transistor MT connected to the word line WL. The voltage VPGM is a voltage higher than the voltage VPASS_PGM.

In a NAND string NS corresponding to the bit line BL(0) to be programmed, the select transistor ST1 is turned ON. Therefore, the channel voltage of the memory cell transistor MT connected to the selected word line WLsel becomes 0 V. The voltage difference between the control gate and the channel becomes large, and as a result, electrons are injected into the charge storage layer 336, so that the threshold voltage of the memory cell transistor MT rises.

In the NAND string NS corresponding to the bit line BL(1) not to be programmed, the select transistor ST1 is cut off. Therefore, the channel of the memory cell transistor MT connected to the selected word line WLsel is electrically floated, so that the channel voltage is raised to near the voltage VPGM by capacitive coupling with the word line WL or the like. The voltage difference between the control gate and the channel is reduced, and as a result, electrons are not injected into the charge storage layer 336, so that the threshold voltage of the memory cell transistor MT is maintained. To be precise, the threshold voltage does not fluctuate to the extent that the threshold voltage thereof transitions to a higher state.

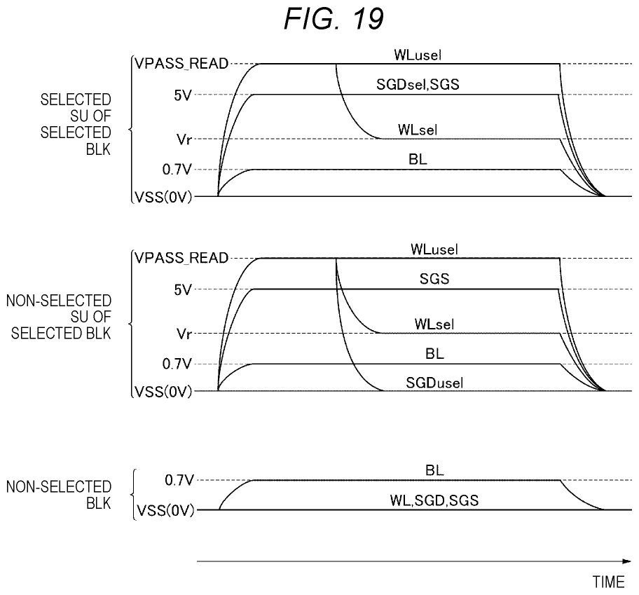

The read operation (also verify operation) will be described. FIG. 19 illustrates voltage changes in various wirings during the read operation. Hereinafter, an example in which the read operation is performed on the plane PL1 will be described. In the read operation, a NAND string NS including a memory cell transistor MT to be read is selected. Alternatively, a string unit SU including a page to be read is selected.

First, for example, 5 V is applied from the voltage generation circuit 43 to the selected select gate line SGDsel, the non-selected select gate line SGDusel, and the select gate line SGS via the row decoder 130. As a result, the select transistor ST1 and the select transistor ST2 included in the selected block BLK are turned ON. Further, for example, the read pass voltage VPASS_READ is applied from the voltage generation circuit 43 to the selected word line WLsel and the non-selected word line via the row decoder 130. The read pass voltage VPASS_READ is a voltage that turns ON the memory cell transistor MT and does not change the threshold voltage regardless of the threshold voltage of the memory cell transistor MT. As a result, a current flows in all the NAND strings NS included in the selected block BLK, regardless of whether the NAND string is the selected string unit SU or the non-selected string unit SU.

Next, for example, a read voltage Vr such as VrA is applied via the row decoder 130 from the voltage generation circuit 43 to the word line WL connected to the memory cell transistor MT to be read (selected word line WLsel). The read pass voltage VPASS_READ is applied to the other word lines WL (non-selected word lines WLusel).

Further, while maintaining the voltage applied to the selected select gate line SGDsel and the select gate line SGS, for example, the voltage Vss is applied from the voltage generation circuit 43 to the non-selected select gate line SGDusel via the row decoder 130. As a result, the select transistor ST1 included in the selected string unit SU is maintained at the ON state, but the select transistor ST1 included in the non-selected string unit SU is turned OFF. Further, the select transistor ST2 included in the selected block BLK is turned ON, regardless of whether the select transistor ST2 belongs to the selected string unit SU or the non-selected string unit SU.

As a result, the NAND string NS included in the non-selected string unit SU does not forma current path because at least the select transistor ST1 is turned OFF. Meanwhile, the NAND string NS included in the selected string unit SU forms or does not form a current path depending on the relationship between the read voltage Vr applied to the selected word line WLsel and the threshold voltage of the memory cell transistor MT.

The sense amplifier 120 applies a voltage to the bit line BL connected to the selected NAND string NS. In this state, the sense amplifier 120 performs read of data based on the amount of current flowing through the bit line BL. Specifically, it is determined whether or not the threshold voltage of the memory cell transistor MT, which is the target of the read operation, is higher than the read voltage applied to the memory cell transistor MT. Alternatively, the data read may be performed based on a temporal change of the voltage in the bit line BL, instead of the amount of current flowing through the bit line BL. In the case of a temporal change of the voltage in the bit line BL, the bit line BL is pre-charged so as to have a predetermined voltage.

The verify operation described above is also performed in the same manner as the read operation as described above. In the verify operation, a verify voltage such as VfyA is applied via the row decoder 130 from the voltage generation circuit 43 to the word line WL connected to the memory cell transistor MT to be verified.

The operation of applying the voltage of 5 V to the selected select gate line SGDsel and the non-selected select gate line SGDusel in the initial stage of the program operation described above may be omitted. Similarly, the operation of applying the voltage of 5V to the non-selected select gate line SGDusel and applying the read pass voltage VPASS_READ to the selected word line WLsel in the initial stage of the read operation (or verify operation) described above maybe omitted.

In the present embodiment, as described above, the one-page data of lower bits (lower page data) maybe determined by the read result using the read voltages VrA and VrE, the one-page data of middle bits (middle page data) may be determined by the read result using the read voltages VrB, VrD, and VrF, and the one-page data of upper bits (upper page data) may be determined by the read result using the read voltages VrC and VrG.

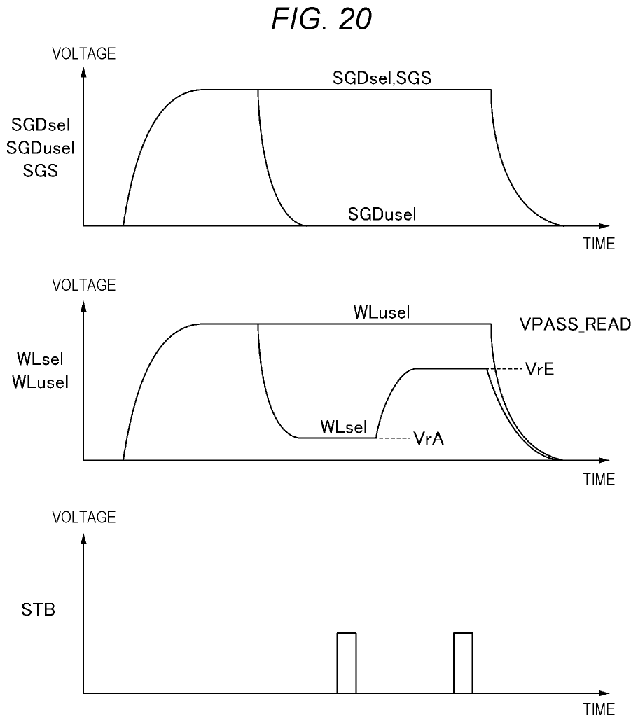

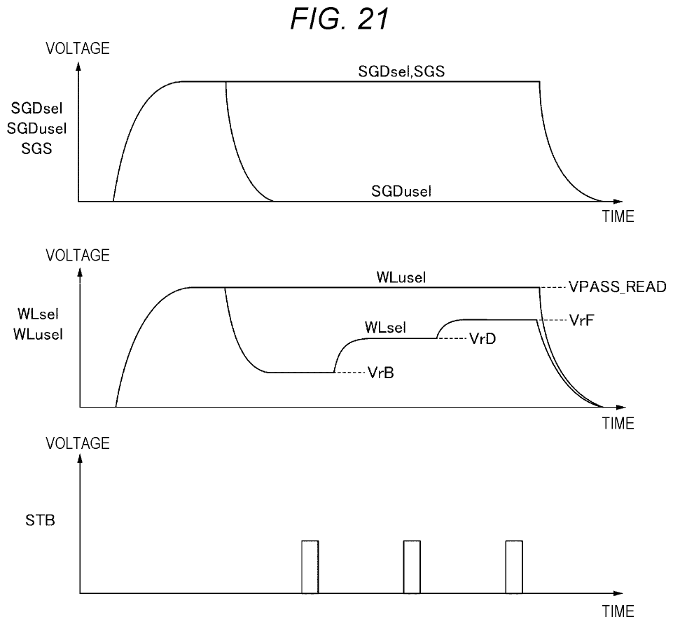

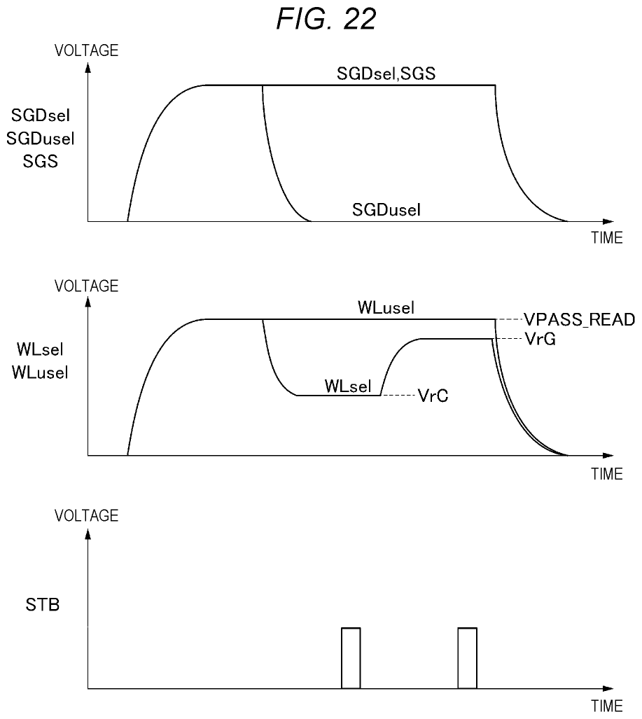

FIG. 20 illustrates an example of the relationship between the voltage applied to the selected word line WLsel in the read operation of the lower page and the control signal STB of the sense amplifier unit SAU. Similarly, FIG. 21 illustrates an example of the relationship between the voltage applied to the selected word line WLsel in the read operation of the middle page and the control signal STB of the sense amplifier unit SAU. Further, FIG. 22 illustrates an example of the relationship between the voltage applied to the selected word line WLsel in the read operation of the upper page and the control signal STB of the sense amplifier unit SAU. The control signal STB is a control signal for performing read of data based on the value of a current flowing through the bit line BL corresponding to the sense amplifier unit SAU.

In the above, the write operation and the read operation in the plane PL1 was described, but the write operation and the like in the plane PL2 are also performed in the same manner as in the case of the plane PL1 as described above.

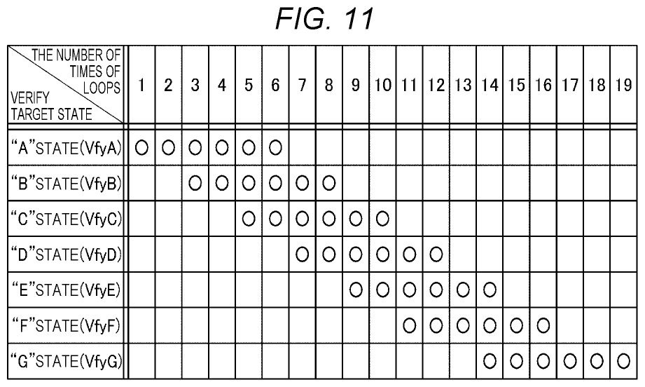

A specific flow of the write operation will be described. In the write operation, the program operation and the verify operation are repeated until it is confirmed that data are written correctly. FIG. 11 represents an example in which data are written by repeating a combination of the program operation and the verify operation 19 times. Each operation repeated in this way is hereinafter referred to as a “loop.”

FIG. 11 represents the target state of the verify operation performed in each loop. As illustrated in the figure, in the first and second loops, the verify operation is performed only for the “A” state. That is, during the verify operation, the voltage VfyA is applied to the selected word line WLsel, and the voltages VfyB to VfyG are not applied to the selected word line WLsel. In the following third and fourth loops, the verify operation is performed for the “A” state and the “B” state. That is, during the verify operation, the verify voltages VfyA and VfyB are sequentially applied to the selected word line WLsel, and the verify voltages VfyC to VfyG are not applied to the selected word line WLsel.

In the fifth and sixth loops, the verify operation is performed for the “A” state, the “B” state, and the “C” state. That is, during the verify operation, the verify voltages VfyA, VfyB, and VfyC are sequentially applied to the selected word line WLsel, and the verify voltages VfyD to VfyG are not applied to the selected word line WLsel. Then, the verify operation for the “A” state is completed in the sixth loop. This is because it is empirically obtained that the program to the “A” state is almost completed in, for example, 6 loops.

In addition, in the seventh and eighth loops, the verify operation is performed for the “B” state, the “C” state, and the “D” state. That is, during the verify operation, the verify voltages VfyB, VfyC, and VfyD are sequentially applied to the selected word line WLsel. Then, the verify operation for the “B” state is completed by the eighth write operation. Further, in the ninth and tenth loops, the verify operation is performed for the “C” state, the “D” state, and the “E” state. That is, during the verify operation, the verify voltages VfyC, VfyD, and VfyE are sequentially applied to the selected word line WLsel. Then, the verify operation for the “C” state is completed in the tenth loop.

After that, the write of the “G” state is performed in the same way. Therefore, the loop is repeated up to 19 times.

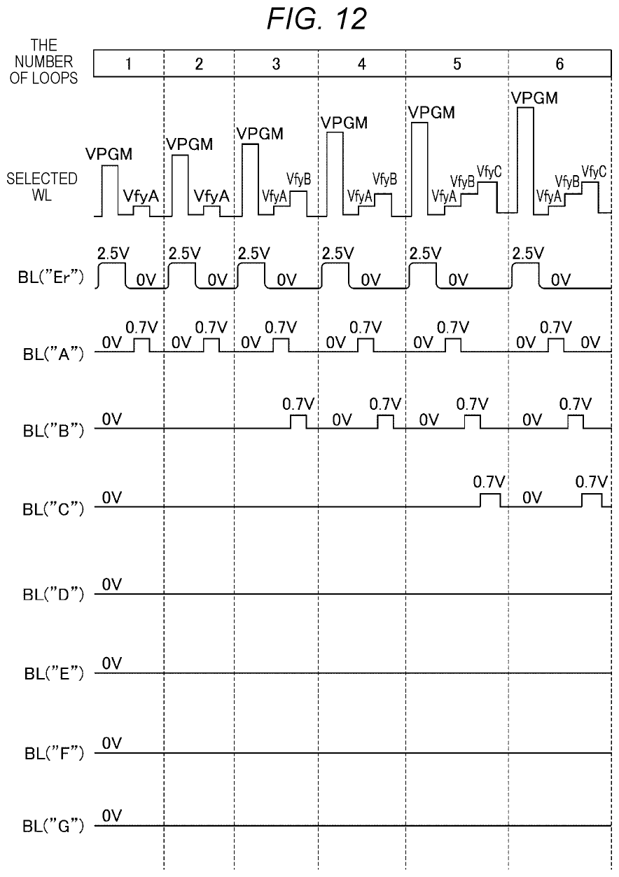

FIG. 12 illustrates the state of the voltage of each wiring during the above-described write operation. FIG. 12 illustrates temporal changes of the voltage of the selected word line WLsel, the voltage of the bit line BL (denoted as BL(“Er”) in FIG. 12) corresponding to the memory cell transistor MT at which the “Er” state should be maintained, the voltages of the bit lines BL (denoted as BL (“A”) , BL(“B”), BL(“C”), BL(“D”), BL(“E”), BL(“F”), and BL(“G”) in FIG. 12) corresponding to the memory cell transistors MT whose thresholds should be raised to values within the “A” to “G” states, in the first to sixth loops

As illustrated, in the first loop, the program operation is performed for the memory cell transistor MT connected to each of the bit lines BL(“A”) to BL(“G”). Specifically, the voltage VPGM is applied to the selected word line WLsel, for example, 2.5V is applied to the bit line BL(“Er”), and for example, the voltage VSS (=0 V) is applied to the bit lines BL (“A”) to BL(“G”). As a result, the threshold voltage of the selected memory cell transistor MT connected to each of the bit lines BL(“A”) to BL(“G”) rises.

Following such a program operation, the verify operation for the “A” state is performed. Specifically, the bit line BL (“A”) is pre-charged with, for example, 0.7V, and the verify voltage VfyA is applied to the selected word line WLsel. The other bit lines BL (“Er”) and BL (“B”) to BL (“G”) are fixed to, for example, 0 V and are excluded from the verify target. As a result, as described above with reference to FIG. 11, in the first loop, the verify operation is performed only for the “A” state.

In the second loop, the program operation is performed for the memory cell transistor MT connected to each of the bit line BL (“A”) and the bit lines BL (“B”) to BL (“G”) that failed the verify operation for the “A” state in the first loop. At this time, the voltage VPGM applied to the selected word line WLsel is stepped up so as to be slightly larger than the voltage VPGM in the first loop. Thereafter, the verify operation for the “A” state is executed as in the first loop. That is, even in the second loop, the verify operation is performed only for the “A” state.

In the third loop, as in the second loop, the program operation is performed for the memory cell transistor MT connected to each of the bit line BL(“A”) and the bit lines BL (“B”) to BL (“G”) that failed the verify operation for the “A” state. At this time, the voltage VPGM applied to the selected word line WLsel is further stepped up so as to be slightly larger than the voltage VPGM in the second loop. Thereafter, the verify operation for the “A” state is first executed as in the first and second loops.

Subsequently, the verify operation for the “B” state is executed. Specifically, the bit lines BL (“A”) and BL (“B”) are pre-charged with, for example, 0.7 V, and the verify voltages VfyA and VfyB are sequentially applied to the selected word line WLsel. The other bit lines BL (“Er”) and BL (“C”) to BL (“G”) are fixed to, for example, 0 V and are excluded from the verification target. As a result, as described above with reference to FIG. 11, in the third loop, the verify operation is performed for the “A” state and the “B” state.

In the fourth loop, the voltage VPGM is further stepped up and the same operation as in the third loop is performed.

In the fifth loop, the program operation is performed for the memory cell transistor MT connected to each of the bit lines BL (“A”) , BL(“B”), and BL (“C”) . Subsequently, the verify operation is performed for the “A” state, the “B” state, and the “C” state. In the sixth loop, the voltage VPGM is stepped up and the same operation as in the fifth loop is performed.

Even after the seventh loop, the same program operation and verify operation as above are repeated. As a result, the application of the voltage VPGM and the application of the verify voltage VfyA and the like are alternately repeated for the selected word line WLsel.

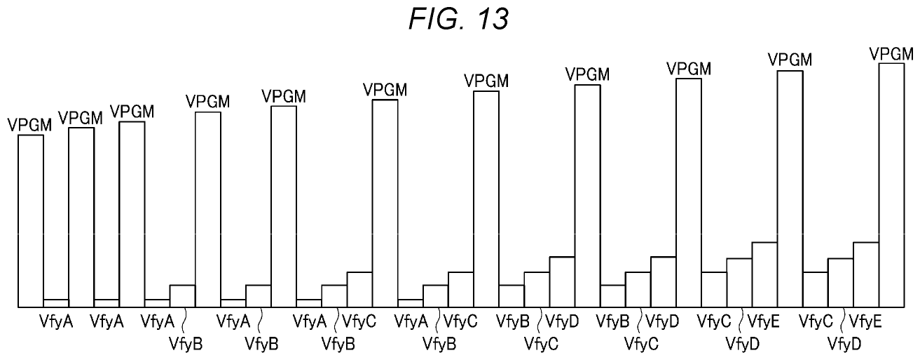

As illustrated in FIG. 12, in each loop, the application of the verify voltage VfyA and the like following the application of the voltage VPGM is repeated once or more. The number of times of applications of the verify voltage VfyA and the like repeated in each loop is in a range of 1 to 3 in the example of FIG. 12, but the number of times of applications may be different from this example. A graph of FIG. 13 schematically shows the state in which the voltage VPGM and the verify voltage VfyA and the like are repeatedly applied to the selected word line WLsel.

In the semiconductor storage device 2 according to the present embodiment, when the write operation or the erase operation is performed on one plane (e.g., the plane PL1), the read operation may be performed on the other plane (e.g., the plane PL2) in parallel with the write operation or the erase operation. An example of such an operation will be described with reference to FIGS. 14A to 14F.

FIG. 14A shows the timing at which a control signal related to the operation of the plane PL1 is input to the interface circuit 20. FIG. 14B shows the timing at which a control signal related to the operation of the plane PL2 is input to the interface circuit 20.

FIG. 14C shows a change in the voltage (the voltage VPGM, the verify voltage VfyA, etc.) applied to the selected word line WLsel in the plane PL1 that performs the write operation. FIGS. 14D, 14E, and 14F each represent changes in the voltage (the read voltage VrA, etc.) applied to the selected word line WLsel in the plane PL2 that performs the read operation. As will be described later, a voltage actually applied to the selected word line WLsel changes as illustrated in any one of FIGS. 14D, 14E, and 14F.

As illustrated in FIG. 14A, in this example, at time to, a control signal PG for causing the plane PL1 to perform the write operation is input to the interface circuit 20. The control signal PG includes a signal that specifies a plane to be operated, a signal that requests the write operation, and a signal that indicates an address or write data to be written.

After time t0, the write operation is performed on the plane PL1. That is, the program operation and the verify operation as described with reference to FIG. 12 and the like are repeatedly executed on the plane PL1. As illustrated in FIG. 14C, after time t0, the voltage VPGM and the verify voltage VfyA are repeatedly applied to the selected word line WLsel of the plane PL1. In this example, the voltage VPGM is applied four times in total in the program operation, and after each program operation, the verify operation for the “A” state is performed once.

In the example of FIG. 14C, the timing at which the program operation is started, that is, the timing at which the voltage VPGM is applied, is times t0, t2, t4, and t6. Further, the timing at which the program operation is ended and the verify operation is started, that is, the timing at which the verify voltage VfyA is applied is times t1, t3, t5, and t7. Time t8 is the timing at which the final verify operation is ended. In FIG. 14C, the timing at which the program operation is ended and the timing at which the subsequent verify operation is started are drawn to be the same, but their actual timings may be different from each other as in the example illustrated in FIG. 12.

As illustrated in FIG. 14B, in this example, at time t10 after time t0, a control signal RD for causing the plane PL2 to perform the read operation is input to the interface circuit 20. The control signal RD includes a signal for specifying a plane to be operated, a signal for requesting the read operation, and a signal indicating an address to be read. In this example, time t10 at which the control signal RD is input is the timing after time t1 and before time t2, that is, the timing during the execution of the first verify operation on the plane PL1.

Even when the control signal RD is input, the corresponding read operation of the plane PL2 is not started at that time (time t10). The read operation of the plane PL2 is started at time t3 at which the next verify operation is started in the plane PL1, as illustrated in FIGS. 14D, 14E, and 14F.

As illustrated in FIG. 9, when the upper page data are read, the read is performed using the read voltages VrC and VrG, and data are determined by the respective results. In this case, in the read operation of the plane PL2, the read voltage applied to the selected word line WLsel changes as illustrated in FIG. 14D. In this case, after the control signal RD is input, the read using the read voltage VrC is performed in a period during which the next verify operation is performed on the plane PL1, that is, in a period from time t3 to time t4. Further, the read using the read voltage VrG is performed in a period during which the further next verify operation is performed on the plane PL1, that is, in a period from time t5 to time t6. It is unnecessary to reset the voltage of the selected word line WLsel to 0V over from time t4 to time t5. For example, the voltage of the selected word line WLsel may be maintained at the read voltage VrC over from time t4 to time t5. Alternatively, the voltage of the selected word line WLsel may be smoothly changed from the read voltage VrC to the read voltage VrG over from time 4 to time t5. The same applies to other figures illustrating the state of parallel operation according to the present embodiment.

As illustrated in FIG. 9, when the middle page data are read, the read is performed using the read voltages VrB, VrD, and VrF, and data are determined by the respective results. In this case, in the read operation of the plane PL2, the read voltage applied to the selected word line WLsel changes as illustrated in FIG. 14E. In this case, after the control signal RD is input, the read using the read voltage VrB is performed in a period during which the next verify operation is performed on the plane PL1, that is, in a period from time t3 to time t4. Further, the read using the read voltage VrD is performed in a period during which the further next verify operation is performed on the plane PL1, that is, in a period from time t5 to time t6. Further, the read using the read voltage VrF is performed in a period during which the furthermore next verify operation is performed on the plane PL1, that is, in a period from time t7 to time t8.

As illustrated in FIG. 9, when the lower page data are read, the read is performed using the read voltages VrA and VrE, and data are determined by the respective results. In this case, in the read operation of the plane PL2, the read voltage applied to the selected word line WLsel changes as illustrated in FIG. 14F. In this case, after the control signal RD is input, the read using the read voltage VrA is performed in a period during which the next verify operation is performed on the plane PL1, that is, in a period from time t3 to time t4. Further, the read using the read voltage VrE is performed in a period during which the further next verify operation is performed on the plane PL1, that is, in a period from time t5 to time t6.

As described above, the read voltage applied to the selected word line WLsel changes as illustrated in any of FIGS. 14D, 14E, and 14F depending on the type of page data (that is, either upper, middle, or lower) for which the read operation is to be performed. In any case, the read operation on the plane PL2 is executed in accordance with the timing when the verify operation on the plane PL1 is performed. The process required for such timing adjustment is performed by the sequencer 41 which is a control circuit.

According to a request from the memory controller 1, the sequencer 41 performs a process required to transmit a status signal indicating the operation state of each of the planes PL1 and PL2 to the memory controller 1 via the interface circuit 20 (specifically, the input/output circuit 21). Specifically, the sequencer 41 updates the first status information stored in the first status register 426 based on the operation state of the plane PL1. Further, the sequencer 41 updates the second status information stored in the second status register 427 based on the operation state of the plane PL2. The first status information and the second status information are transmitted from the interface circuit 20, as status signals, in response to a request from the memory controller 1.

For example, in the case of the example illustrated in FIG. 14D, that is, when the upper page data are read in the TLC method, the second status information indicating that the plane PL2 is in the read operation is stored by the sequencer 41 in the second status register 427 in a period from time t3 up to time t6.

In the case of the example illustrated in FIG. 14E, that is, when the middle page data are read in the TLC method, the second status information indicating that the plane PL2 is in the read operation is stored by the sequencer 41 in the second status register 427 in a period from time t3 up to time t8.

In the case of the example illustrated in FIG. 14F, that is, when the lower page data are read in the TLC method, the second status information indicating that the plane PL2 is in the read operation is stored by the sequencer 41 in the second status register 427 in a period from time t3 up to time t6.

Even when the MLC method, the SLC method, or the like is adopted as the method of writing data to the memory cell transistor MT, the read operation on the plane PL2 may be performed at the timing when the verify operation on the plane PL1 is performed, in the same manner as described above. For example, when the SLC method is adopted, the data read using the read voltage VrA and the like is performed only once in a period from time t3 to time t4.

Meanwhile, it is also conceivable to immediately start the read operation on the plane PL2 at time t10 which is the timing at which the control signal RD is input. However, when the read operation on the plane PL2 is started at time t10, the voltage VPGM is applied to the selected word line WLsel of the plane PL1 at time t2 during the read operation. That is, the application of the voltage VPGM on the plane PL1 and the application of the read voltage VrA and the like on the plane PL2 are performed at the same time.

The voltage VPGM is a relatively high voltage as compared with the voltage applied to the bit line BL, the read voltage VrA, and the like. Therefore, when the application of the voltage VPGM on the plane PL1 and the application of the read voltage VrA and the like on the plane PL2 are performed at the same time, a circuit such as the sense amplifier 220 on the plane PL2 is affected by the voltage VPGM, which may result in a malfunction in the plane PL2. Specifically, for example, the voltage of the bit line BL, the voltage of the selected word line WLsel, and the like on the plane PL2 fluctuate under the influence of the voltage VPGM, which may cause a malfunction.

Therefore, in the semiconductor storage device 2 according to the present embodiment, the sequencer 41, which is a control circuit, adjusts the operation timing of the plane PL2 so that the plane PL2 is caused to perform the read operation in a period during which the verify operation is performed on the plane PL1. Specifically, the sequencer 41 starts the read operation on the plane PL2 at the timing when the verify operation is started on the plane PL1. As a result, the application of the voltage VPGM on the plane PL1 and the application of the read voltage VrA and the like on the plane PL2 are not performed at the same time, so that the above-described malfunction may be prevented. Further, the verify operation executed on the plane PL1 and the read operation executed on the plane PL2 in parallel with the verify operation are both the same type of operations performed for reading data. In this way, by performing the same type of operations in parallel, there is an advantage that control becomes easier.

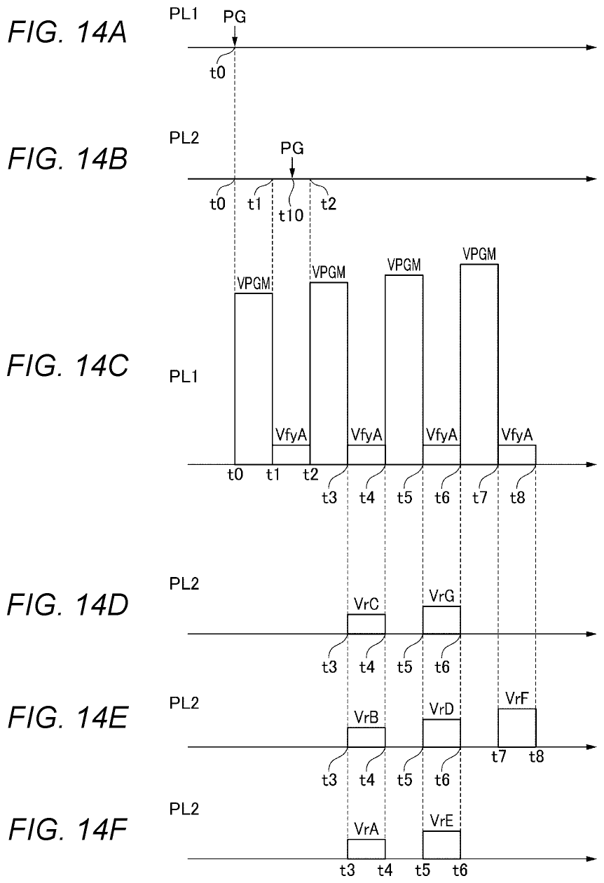

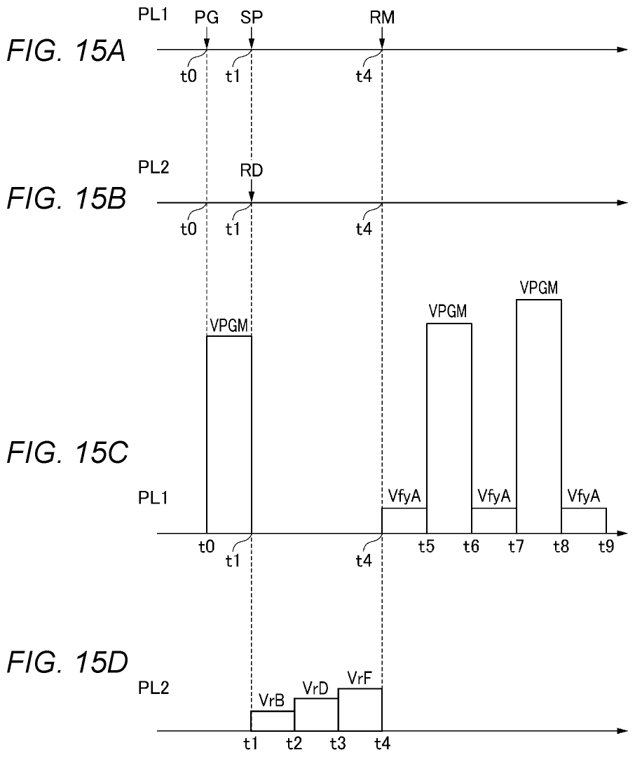

In order to prevent the application of the voltage VPGM on the plane PL1 and the application of the read voltage VrA and the like on the plane PL2 from being performed at the same time, it is also conceivable to perform the read operation on the plane PL2 in a state where the write operation on the plane PL1 is temporarily interrupted. FIGS. 15A to 15D illustrate an example in which the semiconductor storage device 2 operates in this way as a comparative example.

FIG. 15A represents the timing at which a control signal related to the operation of the plane PL1 is input to the interface circuit 20, as in FIG. 14A. FIG. 15B represents the timing at which a control signal related to the operation of the plane PL2 is input to the interface circuit 20, as in FIG. 14B. FIG. 15C represents a change in the voltage (the voltage VPGM, the verify voltage VfyA, etc.) applied to the selected word line WLsel on the plane PL1 that performs the write operation, as in FIG. 14C. FIG. 15D represents a change in the voltage (the read voltage VrB, etc.) applied to the selected word line WLsel on the plane PL2 that performs the read operation, as in FIG. 14E.

Also in this comparative example, at time t0, the control signal PG for causing the plane PL1 to perform the write operation is input to the interface circuit 20. Further, at the subsequent time t1, the control signal RD for causing the plane PL2 to perform the read operation is input to the interface circuit 20.

In the example of FIGS. 15A to 15D, the sequencer 41 temporarily interrupts the write operation on the plane PL1 at time t1. At this time, on the plane PL1, the program operation by the application of the voltage PGRM is completed. However, at this point of time, the verify operation following the program operation is not started.

In order to interrupt the write operation on the plane PL1 as described above, the memory controller 1 may transmit a command for temporarily interrupting the operation of the plane PL1 prior to the transmission of the control signal RD.

After time t1, the read operation on the plane PL2 is performed. For example, when the middle page data is read, the read voltage applied to the selected word line WLsel of the plane PL2 changes as illustrated in FIG. 15D. Specifically, the read using the read voltage VrB is performed in a period from time t1 to time t2. Further, the read using the read voltage VrD is performed in a period from time t2 to time t3. Further, the read using the read voltage VrF is performed in a period from time t3 to time t4.

At time t4, the read operation on the plane PL2 is ended. The memory controller 1 detects that the read operation on the plane PL2 is completed, based on the status signal transmitted from the semiconductor storage device 2.

At this timing, the memory controller 1 restarts the write operation on the plane PL1. Specifically, the memory controller 1 inputs a control signal RM for causing the plane PL1 to restart the write operation to the interface circuit 20 at time t4.

Based on the control signal RM, the sequencer 41 restarts the write operation on the plane PL1. As illustrated in FIG. 15C, from time t4, the first verify operation is performed on the plane PL1. Thereafter, the program operation and the verify operation on the plane PL1 are repeated. In the example of FIG. 15C, the timing at which the program operation is started after restarting, that is, the timing at which the voltage VPGM is applied is times t5 and t7. Further, the timing at which the program operation is ended and the verify operation is started after restarting, that is, the timing at which the verify voltage VfyA is applied is times t6 and t8. Time t9 is the timing at which the final verify operation is ended.

By performing the operation of the comparative example as described above, the application of the voltage VPGM on the plane PL1 and the application of the read voltage VrA and the like on the plane PL2 are not performed at the same time. However, in this case, the write operation of the plane PL1 is interrupted in a period during which the read operation is performed on the plane PL2, that is, a period from time t1 to time t4. As a result, the time required for the write operation becomes long. Further, there is a possibility that data retention (change in threshold voltage) on the plane PL1 may occur in a period during which the write operation is interrupted.

Meanwhile, in the semiconductor storage device 2 according to the present embodiment, as described with reference to FIGS. 14A to 14F, the read operation on the plane PL2 is executed without interrupting the write operation on the plane PL1. Therefore, the above-mentioned problems are overcome and the operation of the semiconductor storage device 2 may be speeded up as compared with the conventional case.

The process as described above is similarly performed when the erase operation is performed on the plane PL1 and when the read operation is performed on the plane PL1. Similar to a general semiconductor storage device, in the semiconductor storage device 2 according to the present embodiment, in the erase operation, data erase by applying a high voltage to the selected word line WLsel and the verify operation are repeatedly executed. Therefore, the timing at which the read operation on the plane PL2 is started may match the timing at which the verify operation as part of the erase operation on the plane PL1 is started.

The process as described above is similarly performed when the write operation or the erase operation is performed on the plane PL2 and when the read operation is performed on the plane PL1 as well. That is, the read operation on the plane PL1 is started at the timing when the verify operation is started on the plane PL2. The specific mode of the process in this case is the same as the mode in which the operation of the plane PL1 and the operation of the plane PL2 are interchanged in the above description.

The process as described above is similarly performed even when the semiconductor storage device 2 is provided with three or more planes. In any case, among a plurality of planes provided in the semiconductor storage device 2, the one that performs the data write operation or the data erase operation for the memory cell array is defined as a “first plane,” and the one that does not perform none of the data write operation and the data erase operation for the memory cell array is defined as a “second plane.” With such a definition, when a control signal instructing the data read operation for the second plane is input to the interface circuit 20 while the first plane is performing the data write operation or the data erase operation, the sequencer 41, which is the control circuit of the present embodiment, causes the second plane to perform the read operation in a period during which the verify operation is performed on the first plane. Specifically, the sequencer 41 causes the second plane to start the read operation at the timing when the verify operation is started on the first plane.

A second embodiment will be described. In the following, points different from the first embodiment will be mainly described, and points common to the first embodiment will be omitted as appropriate.

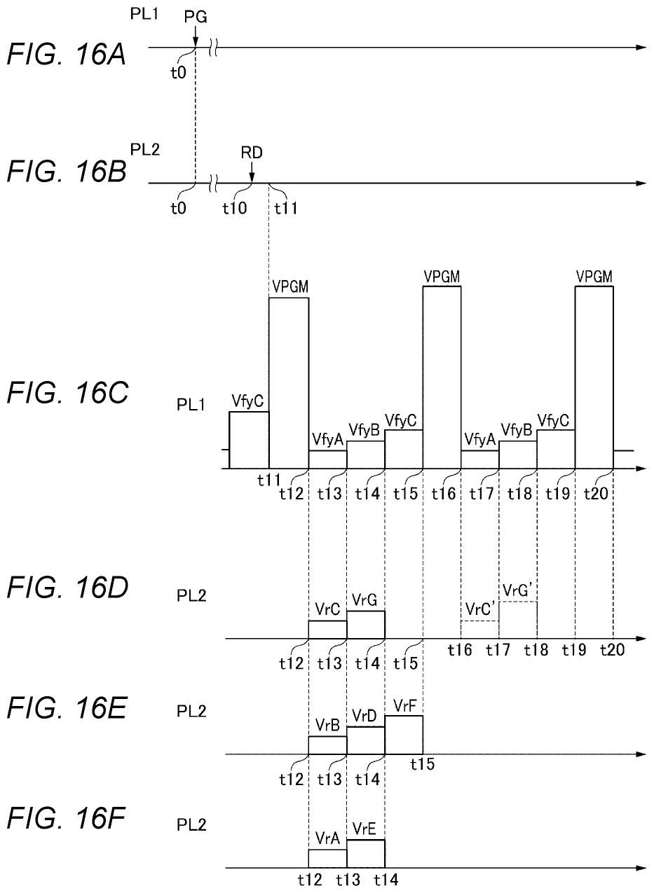

FIGS. 16A to 16F illustrate the operation of a semiconductor storage device 2 according to the second embodiment in the same manner as in FIGS. 14A to 14F. Items illustrated in FIGS. 16A to 16F are the same as the items illustrated in FIGS. 14A to 14F.

As illustrated in FIGS. 16A and 16B, also in the present embodiment, at time t0, the control signal PG for causing the plane PL1 to perform the write operation is input to the interface circuit 20. Further, at time t10 thereafter, the control signal RD for causing the plane PL2 to perform the read operation is input to the interface circuit 20.

As illustrated in FIG. 16C, at time t10, the verify operation is being performed as part of the write operation on the plane PL1. The verify operation is performed until time t11, and the following program operation is performed in a period from time til to time t12.

As illustrated in FIG. 16C, in the present embodiment, in the verify operation following the program operation, the verify operations for three states are performed in order. For example, after the program operation is performed in the period from time t11 to time t12, the verify operation for the “A” state is performed in a period from time t12 to time t13, the verify operation for the “B” state is performed in a period from time t13 to time t14, and the verify operation for the “C” state is performed in a period from time t14 to time t15. Similarly, after the program operation is performed in a period from time t15 to time t16, the verify operation for the “A” state is performed in a period from time t16 to time t17, the verify operation for the “B” state is performed in a period from time t17 to time t18, and the verify operation for the “C” state is performed in a period from time t18 to time t19.

Even when the control signal RD is input at time t10, the corresponding read operation of the plane PL2 is started at time t12 when the next verify operation is started on the plane PL1, as illustrated in FIGS. 14D, 14E, and 14F.

When the upper page data are read, the read voltage applied to the selected word line WLsel on the plane PL2 changes as illustrated in FIG. 16D. In this case, the read using the read voltage VrC is performed in the period from time t12 to time t13. Subsequently, the read using the read voltage VrG is performed in the period from time t13 to time t14.

When the middle page data are read, the read voltage applied to the selected word line WLsel on the plane PL2 changes as illustrated in FIG. 16E. In this case, the read using the read voltage VrB is performed in the period from time t12 to time t13. Further, the read using the read voltage VrD is performed in the period from time t13 to time t14. The read using the read voltage VrF is performed in the period from time t14 to time t15.

When the lower page data are read, the read voltage applied to the selected word line WLsel on the plane PL2 changes as illustrated in FIG. 16F. In this case, the read using the read voltage VrA is performed in the period from time t12 to time t13. Further, the read using the read voltage VrE is performed in the period from time t13 to time t14.

In this way, the read voltage applied to the selected word line WLsel changes as illustrated in any of FIGS. 16D, 16E, and 16F depending on the type of page data (that is, either upper, middle, or lower) for which the read operation is to be performed. In any case, the read operation on the plane PL2 is executed in accordance with the timing when the verify operation on the plane PL1 is performed. Further, in the present embodiment, in any case described above, a period during which the read operation on the plane PL2 is performed is included in a period during which the next verify operation is performed on the plane PL1 after the control signal RD is input (e.g., the period from time t12 to time t15).

In the present embodiment, the verify operations for the three states are performed in order on the plane PL1. Therefore, the period during which the verify operation is performed is longer than that in the case of the first embodiment. Therefore, in the present embodiment, a plurality of states of read operations are continuously performed on the plane PL2 within the period during which the verify operation is performed on the plane PL1.

As the read operation, a read operation, which is a so-called “retry system” in which the read is performed a plurality of times while changing the read voltage, may be performed. Examples of the read operation of the retry system may include “DLA read” and the like.

A period required to execute the read operation of the retry system may not fall within the period during which the verify operation is performed on the plane PL1 (e.g., the period from time t12 to time t15). In this case, as illustrated in FIG. 16D, a part of the read operation of the plane PL2 may be executed in a period during which the next verify operation is performed on the plane PL1 (e.g., a period from time t16 to time t19). In the example of FIG. 16D, the reading using a read voltage VrC′ is performed in a period from time t16 to time t17, and the read using a read voltage VrD′ is performed in a period from time t17 to time t18. The read voltages VrC′ and VrD′ are voltages obtained by slightly changing the read voltages VrC and VrD, respectively.

In this way, when the period required for the read operation on the plane PL2 does not fall within the period of one verify operation on the plane PL1, the read operation of the plane PL2 may be divided into a plurality of parts, and each of the divided read operations may be executed in each period during which the verify operation is performed on the plane PL1. Since the period required for the read operation on the plane PL2 may be obtained in advance by the sequencer 41, it may be flexibly dealt with, for example, by dividing it as described above according to the situations. In any case, the sequencer 41 causes the plane PL2 to perform the read operation within the period during which the verify operation is performed on the plane PL1. Even in such an embodiment, the same effects as those described in the first embodiment are obtained.

A third embodiment will be described. In the following, points different from the first embodiment will be mainly described, and points common to the first embodiment will be omitted as appropriate.

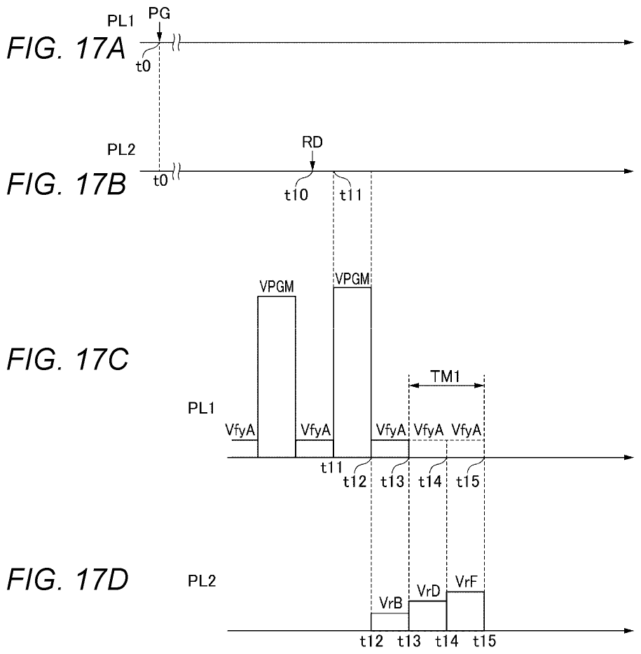

FIGS. 17A to 17D illustrate the operation of a semiconductor storage device 2 according to the third embodiment in the same manner as in FIGS. 14A to 14F. Items illustrated in each of FIGS. 17A to 17C are the same as the items illustrated in each of FIGS. 14A to 14C. Further, FIG. 17D illustrates an example of a change in the voltage applied to the selected word line WLsel of the plane PL2 when reading the middle page data from the plane PL2, as in FIG. 14E.

As illustrated in FIGS. 17A and 17B, also in the present embodiment, the control signal PG for causing the plane PL1 to perform the write operation is input to the interface circuit 20 at time to. Further, at time t10 thereafter, the control signal RD for causing the plane PL2 to perform the read operation is input to the interface circuit 20.

As illustrated in FIG. 17C, time t10 when the control signal RD is input is the timing during which the write operation is being performed on the plane PL1 even in the present embodiment. However, in the example of FIGS. 17A to 17D, time t10 when the control signal RD is input is the timing immediately before the write operation of the plane PL1 is completed.

Specifically, after the verify operation executed on the plane PL1 at time t10 is performed, the final program operation is performed on the plane PL1 in a period from time til to time t12. Subsequently, in a period from time t12 to time t13, the final verify operation is performed on the plane PL1 and the write operation of the plane PL1 is completed at time t13.

Also in the present embodiment, the read operation of the plane PL2 is started at time t12 when the next verify operation is started on the plane PL1. In order to read the middle page data in the read operation of the plane PL2, it is necessary to perform the read of three states using the read voltages VrB, VrD, and VrF, respectively. Therefore, as illustrated in FIG. 17D, the read using the read voltage VrB is performed in the period from time t12 to time t13. Further, the read using the read voltage VrD is performed in the period from time t13 to time t14. The read using the read voltage VrF is performed in the period from time t14 to time t15.

As in this example, when the control signal RD is input at the timing immediately before the write operation of the plane PL1 is completed and the read operation of the plane PL2 is started, the write operation of the plane PL1 is completed at time t13 before time t15 when the read operation of the plane PL2 is completed.

After time t13, there is a possibility that the memory controller 1 instructs the next write operation of the plane PL1. For example, when the next write operation of the plane PL1 is started in any time of the period from time t13 to time t15, the application of the voltage VPGM on the plane PL1 and the application of the read voltage VrD and the like on the plane PL2 are performed at the same time.

Therefore, in the present embodiment, in order to prevent such a state, the sequencer 41 causes the plane PL1 to perform a pseudo-verify operation in a period TM1 from time t13 to time t15. The “pseudo-verify operation” is, for example, a dummy operation for pretending to the memory controller 1 that the verify operation is being performed on the plane PL1. In the pseudo-verify operation, the verify voltage is not applied to the selected word line of the plane PL1.

For example, in the period TM1 during which the pseudo-verify operation is performed, the first status information indicating that the verify operation is not completed on the plane PL1 is stored in the first status register 426. When there is a request from the memory controller 1 in the period TM1, the first status information is output from the input/output circuit 21 to the memory controller 1, as a status signal. The pseudo-verify operation is continuously performed for the same period as when the actual verify operation is performed.

Such a process prevents the next write operation from being started on the plane PL1 during the period from time t13 to time t15, that is, during the period TM1 in which the read operation is performed on the plane PL2.

As described above, in the present embodiment, when the write operation of the plane PL1 is completed before the read operation of the plane PL2 is completed, the sequencer 41, which is the control circuit, causes the plane PL1 to perform the pseudo-verify operation until the read operation of the plane PL2 is completed. Even when the erase operation of the plane PL1 is completed before the read operation of the plane PL2 is completed, the same process as described above is performed.

Further, the process performed in the period TM1 from time t13 to time t15 may be a process different from the above-mentioned “pseudo-verify operation.” For example, in the period TM1, the sequencer 41 may perform only a process necessary for outputting the status signal, which indicates that the plane PL1 is operating, from the interface circuit 20. Specifically, in the period TM1, the sequencer 41 may store the second status information, which indicates that the plane PL1 is operating, in the second status register 427. Even such a method prevents the next write operation from being started on the plane PL1 during the period TM1 in which the read operation is performed on the plane PL2.

As in the above example, when the write operation of the plane PL1 is completed before the read operation of the plane PL2 is completed, the sequencer 41, which is the control circuit, may perform a process necessary for outputting the status signal, which indicates that the plane PL1 is operating, from the interface circuit 20 until the read operation of the plane PL2 is completed. Even when the erase operation of the plane PL1 is completed before the read operation of the plane PL2 is completed, the same process as described above is performed.

A fourth embodiment will be described. In the following, points different from the third embodiment will be mainly described, and points common to the third embodiment will be omitted as appropriate.

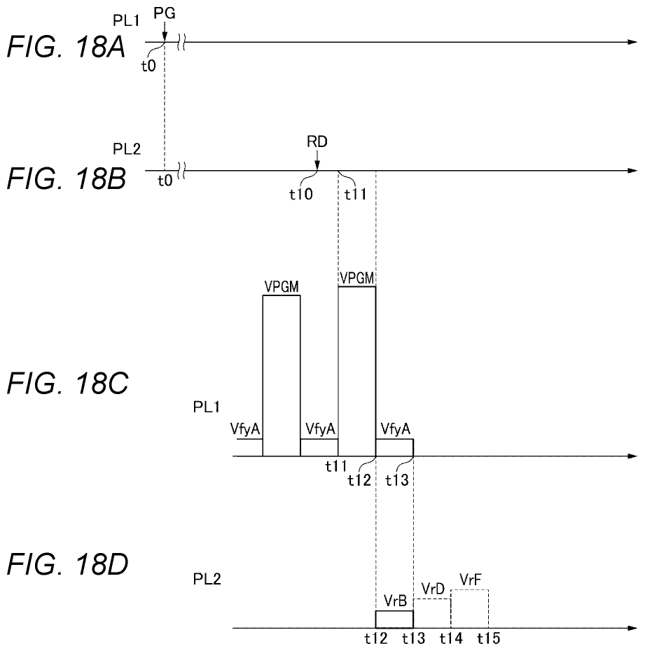

FIGS. 18A to 18D illustrate the operation of a semiconductor storage device 2 according to the fourth embodiment in the same manner as in FIGS. 17A to 17D. Items illustrated in each of FIGS. 18A to 18D are the same as the items illustrated in each of FIGS. 17A to 17D.

As illustrated in FIGS. 18A and 18B, also in the present embodiment, the control signal PG for causing the plane PL1 to perform the write operation is input to the interface circuit 20 at time to. Further, at time t10 thereafter, the control signal RD for causing the plane PL2 to perform the read operation is input to the interface circuit 20.

As illustrated in FIG. 18C, time t10 when the control signal RD is input is the timing immediately before the write operation of the plane PL1 is completed even in the present embodiment. Specifically, after the verify operation executed on the plane PL1 is performed at time t10, the final program operation is performed on the plane PL1 in the period from time til to time t12. Subsequently, in the period from time t12 to time t13, the final verify operation is performed on the plane PL1 and the write operation on the plane PL1 is completed at time t13.

Also in the present embodiment, the read operation of the plane PL2 is started at time t12 when the next verify operation is started on the plane PL1. In order to read the middle page data in the read operation of the plane PL2, it is necessary to perform the read of three states using the read voltages VrB, VrD, and VrF, respectively. Therefore, when the read operation of the plane PL2 is performed in the same manner as in the third embodiment of FIG. 17D, the read operation is completed at time t15 after time t13 when the write operation of the plane PL1 is completed.

Therefore, in the present embodiment, the read operation of the plane PL2 is interrupted at time t13 when the write operation of the plane PL1 is completed. In the example illustrated in FIG. 18D, at time t13, on the plane PL2, the read using the read voltage VrB is completed and the read using the read voltage VrD and the read using the read voltage VrF are not completed.

At time t13, the sequencer 41 stores the second status information, which indicates that the read operation of the plane PL2 is not completed, in the second status register 427. The second status information is output from the input/output circuit 21 to the memory controller 1, as a status signal, in response to a request from the memory controller 1.

Thereafter, when a control signal instructing to perform the read operation of the plane PL2 is transmitted again from the memory controller 1, the read of the three states using the read voltages VrB, VrD, and VrF is executed again. In this case, the process may be restarted from the point of time of the previous interruption.

As described above, in the present embodiment, when the write operation of the plane PL1 is completed before the read operation of the plane PL2 is completed, the sequencer 41, which is the control circuit, performs a process necessary for outputting the status signal, which indicates that the read operation of the plane PL2 is not completed, from the interface circuit 20. Even in such an embodiment, the application of the voltage VPGM on the plane PL1 and the application of the read voltage VrA and the like on the plane PL2 are not performed at the same time. Even when the erase operation of the plane PL1 is completed before the read operation of the plane PL2 is completed, the same process as described above is performed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a plurality of planes, each of which includes a memory cell array, the planes including a first plane and a second plane;
an interface circuit configured to receive and transmit control signals for the planes; and
a control circuit configured to control the planes based on the control signals, wherein
while a first operation that includes multiple loops of a high voltage operation and a verify operation is being performed by the first plane, the control circuit controls the second plane to perform a second operation during at least one period in which the verify operation is performed by the first plane.

2. The semiconductor storage device according to claim 1, wherein the first operation is an erase operation or a data write operation and the second operation is a data read operation.

3. The semiconductor storage device according to claim 1, wherein the control circuit performs a process for outputting a status signal, which indicates the state of each of the planes, from the interface circuit.

4. The semiconductor storage device according to claim 3, wherein
when the first operation is completed before the second operation, the control circuit performs a process for outputting the status signal, which indicates that the first plane is operating, from the interface circuit until the second operation is completed.

5. The semiconductor storage device according to claim 3, wherein
when the first operation is completed before the second operation, the control circuit performs a process for outputting the status signal, which indicates that the second operation has not been completed, from the interface circuit.

6. The semiconductor storage device according to claim 1, wherein
the first operation is a write operation to program 3-bit data into memory cells of the memory cell array of the first plane, and the second operation is a read operation to read 3-bit data from memory cells of the memory cell array of the second plane.

7. The semiconductor storage device according to claim 6, wherein
the verify operation of one of the loops includes successive first, second, and third periods during which first, second, and third verify voltages are applied, and
during the verify operation of said one of the loops, the read operation is performed to read one of lower page data, middle page data, and upper page data from the memory cells of the memory cell array of the second plane.

8. The semiconductor storage device according to claim 7, wherein the lower page data or the upper page data are read during the first and second periods, and the middle page data are read during the first, second, and third periods.

9. The semiconductor storage device according to claim 7, wherein said one of lower page data, middle page data, and upper page data are read again from the memory cells of the memory cell array of the second plane during the verify operation of another one of the loops.

10. The semiconductor storage device according to claim 1, wherein
the control circuit controls the second plane to perform no operation during the high voltage operation of any of the loops of the first operation.

11. A method of concurrently performing a read operation and a write operation in a semiconductor storage device comprising a plurality of planes, each of which includes a memory cell array, the planes including a first plane and a second plane, said method comprising:
while a write operation that includes multiple loops of a program operation and a verify operation is being performed by the first plane, performing a read operation during at least one period in which the verify operation is performed by the first plane.

12. The method according to claim 11, further comprising:
outputting a status signal, which indicates the state of each of the planes.

13. The method according to claim 12, wherein
when the write operation is completed before the read operation, outputting the status signal, which indicates that the first plane is operating, until the read operation is completed.

14. The method according to claim 13, wherein
when the write operation is completed before the read operation, outputting the status signal, which indicates that the read operation has not been completed.

15. The method according to claim 11, wherein
the write operation is a write operation to program 3-bit data into memory cells of the memory cell array of the first plane, and the read operation is a read operation to read 3-bit data from memory cells of the memory cell array of the second plane.

16. The method according to claim 15, wherein
the verify operation of one of the loops includes successive first, second, and third periods during which first, second, and third verify voltages are applied, and
during the verify operation of said one of the loops, the read operation is performed to read one of lower page data, middle page data, and upper page data from the memory cells of the memory cell array of the second plane.

17. The method according to claim 16, wherein the lower page data or the upper page data are read during the first and second periods, and the middle page data are read during the first, second, and third periods.

18. The method according to claim 16, wherein said one of lower page data, middle page data, and upper page data are read again from the memory cells of the memory cell array of the second plane during the verify operation of another one of the loops.

19. The method according to claim 11, wherein
the second plane performs no operation during the program operation of any of the loops of the write operation.

20. A method of concurrently performing an erase operation and a write operation in a semiconductor storage device comprising a plurality of planes, each of which includes a memory cell array, the planes including a first plane and a second plane, said method comprising:
while an erase operation that includes multiple loops of a high voltage apply operation and a verify operation is being performed by the first plane, performing a read operation during at least one period in which the verify operation is performed by the first plane,
wherein the second plane performs no operation during the high voltage apply operation of any of the loops of the erase operation.
